(19) United States
(12) Patent Application Publication
(10) Pub. No.: US 2025/0015149 A1
(43) Pub. Date: Jan. 9, 2025

(54) SEMICONDUCTOR DEVICE FOR POWER AMPLIFICATION

(71) Applicant: Nuvoton Technology Corporation Japan, Kyoto (JP)

(72) Inventors: Katsuhiko KAWASHIMA, Hyogo (JP); Yoshiaki KATOU, Toyama (JP); Kaname MOTOYOSHI, Hyogo (JP)

(21) Appl. No.: 18/894,473

(22) Filed: Sep. 24, 2024

Related U.S. Application Data
(63) Continuation of application No. PCT/JP2023/005730, filed on Feb. 17, 2023.
(60) Provisional application No. 63/324,387, filed on Mar. 28, 2022.
(60) Provisional application No. 63/324,402, filed on Mar. 28, 2022.

(51) Int. Cl. H01L 29/417; H01L 29/20; H01L 29/40; H01L 29/66; H01L 29/778

(52) U.S. Cl. CPC H01L 29/4175; H01L 29/2003; H01L 29/401; H01L 29/402; H01L 29/66462; H01L 29/7786

(57) ABSTRACT

A semiconductor device for power amplification includes a lower electrode, a semiconductor layer, a source electrode, a drain electrode, and a gate electrode. The semiconductor layer is divided into an active region and an isolation region. A channel region includes unit channel regions that are separated by the isolation region. The source electrode includes unit source electrodes each of which faces a corresponding one of the unit channel regions. Unit source regions each include at least one source via that contains a conductor in contact with the lower electrode, the unit source regions each including a corresponding one of the unit source electrodes. In a plan view, a length of a side of a minimum rectangular region in an X-axis direction is greater than a length of a side of the minimum rectangular region in the Y-axis direction, the minimum rectangular region surrounding the at least one source via.

### CROSS REFERENCE TO RELATED APPLICATIONS

This is a continuation application of PCT International Application No. PCT/JP2023/005730 filed on Feb. 17, 2023, designating the United States of America, which is based on and claims priority of U.S. Patent Application No. 63/324,387 filed on Mar. 28, 2022 and U.S. Patent Application No. 63/324,402 filed on Mar. 28, 2022. The entire disclosures of the above-identified applications, including the specifications, drawings and claims are incorporated herein by reference in their entirety.

### FIELD

The present disclosure relates to a semiconductor device for power amplification.

### BACKGROUND

Patent Literature (PTL) 1 discloses a high-electron-mobility transistor (HEMT) that uses two-dimensional electron gas (2DEG) as a channel.

### CITATION LIST

### Patent Literature

PTL 1: Japanese Patent No. 5390768

### SUMMARY

### Technical Problem

The properties of semiconductor devices such as high-electron-mobility transistors degrade due to heat generated during operation.

In view of this, the present disclosure provides a semiconductor device for power amplification that is capable of reducing property degradation due to heat.

### Solution to Problem

A semiconductor device for power amplification according to one aspect of the present disclosure comprising: a substrate; a lower electrode provided below the substrate; a semiconductor layer that is provided above the substrate and includes a plurality of active layers comprising group-III nitride, and in which two-dimensional electron gas is produced in a hetero interface of the plurality of active layers; a source electrode and a drain electrode that are provided above the semiconductor layer, spaced apart from each other, and electrically connected to the two-dimensional electron gas; a gate electrode that is spaced apart from the source electrode and the drain electrode and is in contact with the semiconductor layer; a gate finger that is in contact with and covers all of a plurality of gate electrodes arranged linearly in a first direction, the plurality of gate electrodes each being the gate electrode; and a drain finger that is in contact with and covers all of a plurality of drain electrodes arranged linearly in the first direction, the plurality of drain electrodes each being the drain electrode, wherein a plurality of gate fingers are arranged in a second direction orthogonal to the first direction and supplied with a same electric potential, the plurality of gate fingers each being the gate finger, in a plan view of the substrate, the semiconductor layer is divided into an active region containing the two-dimensional electron gas and an isolation region not containing the two-dimensional electron gas, in the plan view, a channel region includes a plurality of unit channel regions that are separated by the isolation region and arranged in the first direction, the channel region being an overlapping portion of the active region and the plurality of gate electrodes, the source electrode includes a plurality of unit source electrodes each of which faces a corresponding one of the plurality of unit channel regions, a plurality of unit source regions each include at least one source via that contains a conductor that penetrates through the substrate and the semiconductor layer and is in contact with the lower electrode that is supplied with a same electric potential as an electric potential supplied to the source electrode, the plurality of unit source regions each including a corresponding one of the plurality of unit source electrodes, and in the plan view, a length of a side of a minimum rectangular region in the second direction is greater than a length of a side of the minimum rectangular region in the first direction, the minimum rectangular region surrounding the at least one source via.

### Advantageous Effects

A semiconductor device for power amplification according to the present disclosure makes it possible to reduce property degradation due to heat.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a plan view of a semiconductor device for power amplification according to an embodiment.

FIG. 2 is a cross-sectional view of the semiconductor device for power amplification according to the embodiment, taken along line II-II shown in FIG. 1.

FIG. 3 is a cross-sectional view of the semiconductor device for power amplification according to the embodiment, taken along line III-III shown in FIG. 1.

FIG. 4 is a cross-sectional view of the semiconductor device for power amplification according to the embodiment, taken along line IV-IV shown in FIG. 1.

FIG. 5 is a plan view of an enlarged characterizing portion of the semiconductor device for power amplification according to the embodiment.

FIG. 6 is a cross-sectional view of the semiconductor device for power amplification according to the embodiment, taken along line VI-VI shown in FIG. 5.

FIG. 7 is a cross-sectional view of the semiconductor device for power amplification according to the embodiment, taken along line VII-VII shown in FIG. 5.

FIG. 8 is a plan view of a semiconductor device for power amplification according to a comparative example.

FIG. 9 is a cross-sectional view of the semiconductor device for power amplification according to the comparative example, taken along line IX-IX shown in FIG. 8.

FIG. 10 is a plan view of an example of application of the semiconductor device for power amplification according to the embodiment.

FIG. 11 is a cross-sectional view of the example of application of the semiconductor device for power amplification according to the embodiment, taken along XI-XI line shown in FIG. 10.

FIG. 12 is a cross-sectional view of a semiconductor device for power amplification according to Variation 1 of the embodiment.

FIG. 13 is an XZ cross-sectional view of a semiconductor device for power amplification according to Variation 2 of the embodiment, cutting through a plate drive line.

FIG. 14 is a cross-sectional view of a semiconductor device for power amplification according to Variation 3 of the embodiment.

FIG. 15 is a cross-sectional view of a semiconductor device for power amplification according to Variation 4 of the embodiment.

FIG. 16 is a cross-sectional view of a semiconductor device for power amplification according to Variation 5 of the embodiment.

FIG. 17 is a plan view of another example of a source via in each of the semiconductor devices for power amplification according to the embodiment and Variations 1 to 5.

FIG. 18 is a plan view of another example of the source via in each of the semiconductor devices for power amplification according to the embodiment and Variations 1 to 5.

FIG. 19 is a plan view of another example of the source via in each of the semiconductor devices for power amplification according to the embodiment and Variations 1 to 5.

FIG. 20 is a plan view of another example of the source via in each of the semiconductor devices for power amplification according to the embodiment and Variations 1 to 5.

FIG. 21 is a plan view of another example of the source via in each of the semiconductor devices for power amplification according to the embodiment and Variations 1 to 5.

FIG. 22 is a plan view of another example of the source via in each of the semiconductor devices for power amplification according to the embodiment and Variations 1 to 5.

FIG. 23 is a plan view of another example of the source via in each of the semiconductor devices for power amplification according to the embodiment and Variations 1 to 5.

FIG. 24 is a plan view of another example of the source via in each of the semiconductor devices for power amplification according to the embodiment and Variations 1 to 5.

FIG. 25 is a plan view of another example of the source via in each of the semiconductor devices for power amplification according to the embodiment and Variations 1 to 5.

FIG. 26 is a plan view of another example of a plate drive line in each of the semiconductor devices for power amplification according to the embodiment and Variations 1 to 5.

FIG. 27 is a plan view of another example of the plate drive line in each of the semiconductor devices for power amplification according to the embodiment and Variations 1 to 5.

FIG. 28 is a plan view of another example of the plate drive line in each of the semiconductor devices for power amplification according to the embodiment and Variations 1 to 5.

FIG. 29 is a plan view of another example of the plate drive line and the source via in each of the semiconductor devices for power amplification according to the embodiment and Variations 1 to 5.

FIG. 30A is a cross-sectional view for illustrating a process in a method for manufacturing each of the semiconductor devices for power amplification according to the embodiment and Variations 1 to 5.

FIG. 30B is a cross-sectional view for illustrating a process in the method for manufacturing each of the semiconductor devices for power amplification according to the embodiment and Variations 1 to 5.

FIG. 30C is a cross-sectional view for illustrating a process in the method for manufacturing each of the semiconductor devices for power amplification according to the embodiment and Variations 1 to 5.

FIG. 30D is a cross-sectional view for illustrating a process in the method for manufacturing each of the semiconductor devices for power amplification according to the embodiment and Variations 1 to 5.

FIG. 30E is a cross-sectional view for illustrating a process in the method for manufacturing each of the semiconductor devices for power amplification according to the embodiment and Variations 1 to 5.

FIG. 30F is a cross-sectional view for illustrating a process in the method for manufacturing each of the semiconductor devices for power amplification according to the embodiment and Variations 1 to 5.

FIG. 30G is a cross-sectional view for illustrating a process in the method for manufacturing each of the semiconductor devices for power amplification according to the embodiment and Variations 1 to 5.

FIG. 30H is a cross-sectional view for illustrating a process in the method for manufacturing each of the semiconductor devices for power amplification according to the embodiment and Variations 1 to 5.

### DESCRIPTION OF EMBODIMENT

### Summary of the Present Disclosure

Hereinafter, an embodiment is described in detail with reference to the Drawings.

It should be noted that the embodiment described below shows a generic or specific example. The numerical values, shapes, materials, constituent elements, the arrangement and connection of constituent elements, steps, the order of steps, etc. indicated in the following embodiment are mere examples and are not intended to limit the present disclosure. In addition, among the constituent elements in the following embodiment, constituent elements not recited in any one of the independent claims are described as arbitrary constituent elements.

Moreover, the respective figures are schematic diagrams and are not necessarily precise illustrations. Accordingly, the figures are not necessarily to scale etc. Furthermore, for example, in each figure, the thickness, size, etc. of a constituent element may be exaggerated for the sake of easy-to-understand explanation. Additionally, the same reference signs are assigned to substantially identical elements in the respective figures, and overlapping descriptions thereof are omitted or simplified.

Moreover, in this Specification, terms indicating the relationship between elements such as parallel or orthogonal, terms indicating the shape of elements such as rectangular or circular, and numerical ranges are not expressions that indicate only the strict meaning but are expressions that mean a substantially equivalent range, and include, for example, an error of approximately several percent.

Furthermore, in this Specification, the terms “above” and “below” do not refer to the upward (vertically upward) direction and downward (vertically downward) direction in terms of absolute spatial recognition, and are used as terms defined by relative positional relationships based on the stacking order of a stacked configuration. In addition, the terms “above” and “below” are applied not only when two constituent elements are arranged at intervals without another constituent element located between the two constituent elements, but also when two constituent elements are arranged adjacent to each other.

Moreover, in this Specification and the drawings, an X-axis, a Y-axis, and a Z-axis represent three axes in a three-dimensional orthogonal coordinate system. In each embodiment, a Z-axis direction is defined as the thickness direction of a substrate. In addition, in this Specification, the “thickness direction” means the thickness direction of a substrate and refers to a direction perpendicular to the principal surface of the substrate. A Y-axis direction is an example of a first direction, and is a direction in which a gate finger and a drain finger extend. An X-axis direction is an example of a second direction, and is a direction in which a source electrode, a gate electrode, and a drain electrode are arranged in stated order. Additionally, unless otherwise noted, a “plan view” refers to a view from the direction perpendicular to the principal surface of the substrate.

Furthermore, in this Specification, a layer that comprises group-III nitride is a semiconductor layer that contains at least one type of group-III elements and nitrogen. Examples of a group-III element include aluminum (AI), gallium (Ga), and indium (In). Examples of group-III nitride include GaN, AlN, InN, AlGaN, InGaN, and AlInGaN. Group-III nitride may contain at least one type of elements other than a group-III element, such as silicon (Si) and phosphorus (P). It should be noted that, in the following description, unless otherwise noted, when group-III nitride is expressed as AlInGaN, such an expression means that the group-III nitride contains all of Al, In, Ga, and N. The same applies to other expressions such as AlGaN and GaN.

Moreover, a layer that comprises group-III nitride means that the layer contains substantially only the group-III nitride. However, the layer may contain, as impurities, other elements such as elements the mixing of which is inevitable in manufacturing, at a rate of at most 1%.

Furthermore, in this Specification, unless otherwise noted, the ordinal such as “first” and “second” does not mean the number or order of constituent elements, and is used for the purpose of avoiding confusion about constituent elements of the same type and distinguishing them from each other.

### Embodiment

### 1. Configuration

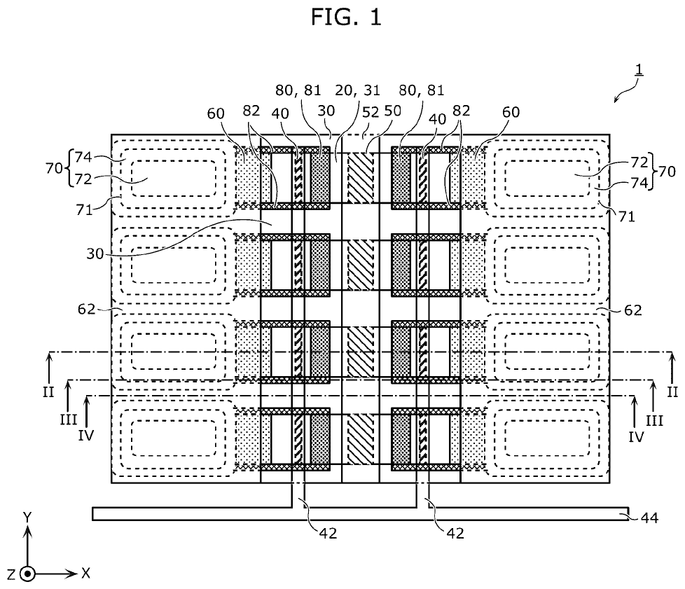

First, a configuration of a semiconductor device for power amplification according to an embodiment is described with reference to FIG. 1 to FIG. 7.

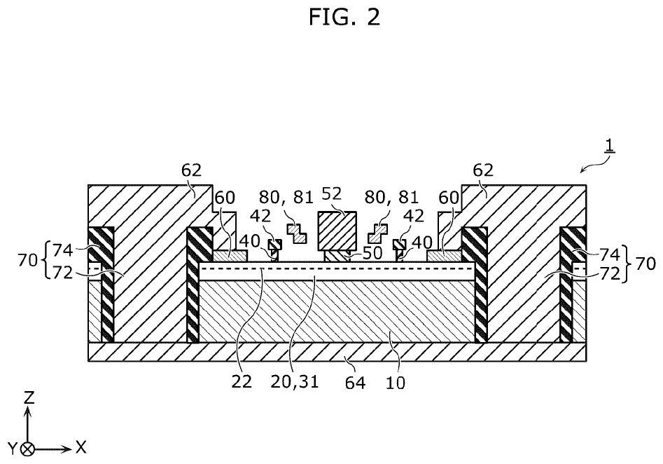

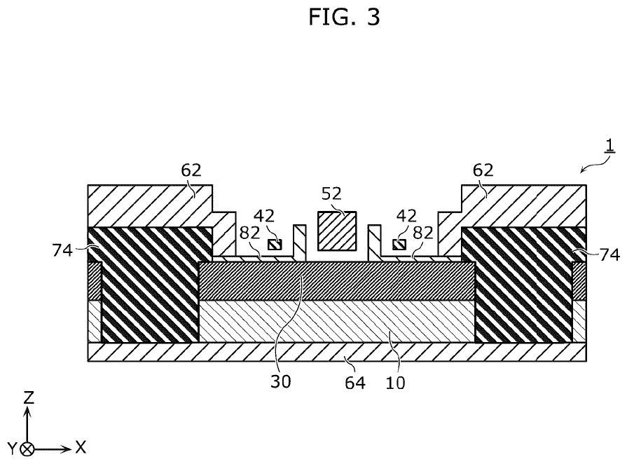

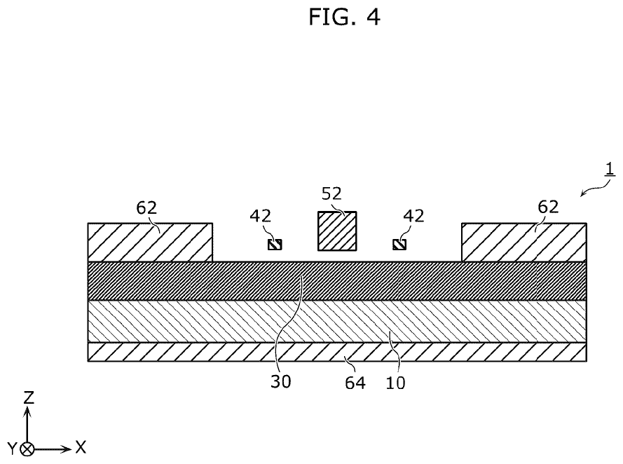

FIG. 1 is a plan view of the semiconductor device for power amplification according to the embodiment. FIG. 2 to FIG. 4 each are a cross-sectional view of the semiconductor device for power amplification according to the embodiment. Specifically, FIG. 2 shows a cross section taken along line II-II shown in FIG. 1. FIG. 3 shows a cross section taken along line III-III shown in FIG. 1. FIG. 4 shows a cross section taken along line IV-IV shown in FIG. 1.

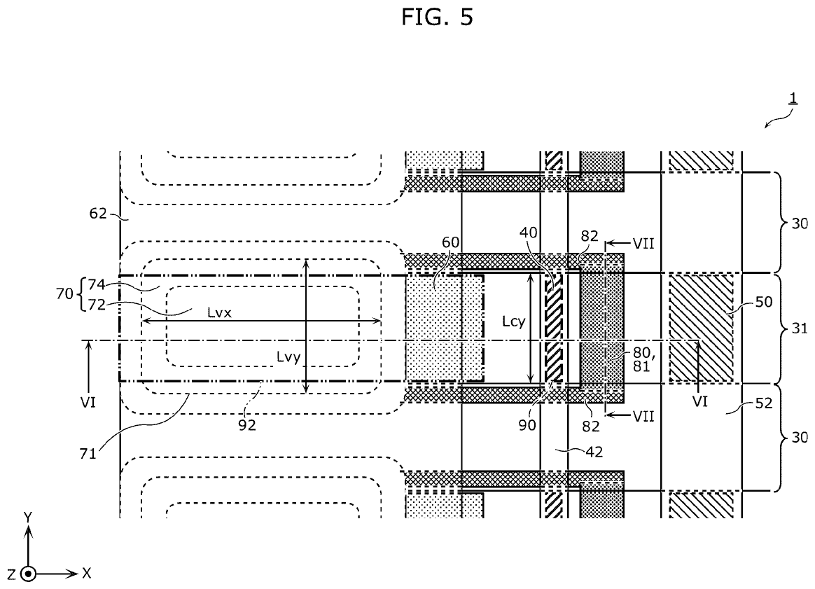

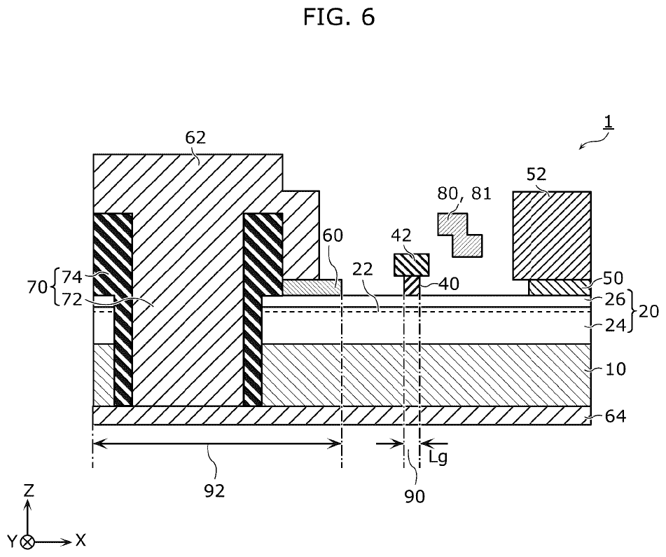

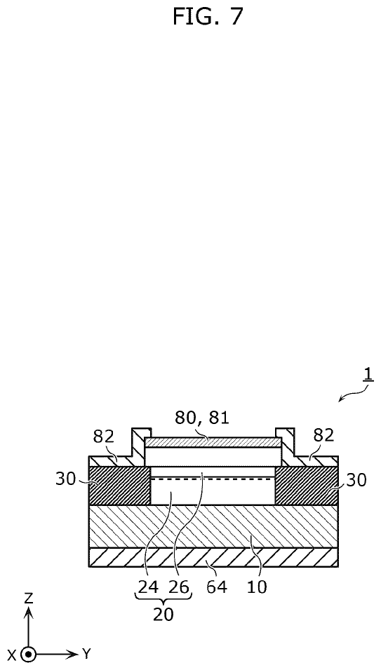

FIG. 5 is a plan view of an enlarged characterizing portion of the semiconductor device for power amplification according to the embodiment. FIG. 5 shows a positional relationship between constituent elements in more detail than FIG. 1. FIG. 6 and FIG. 7 each are a plan view of the semiconductor device for power amplification according to the embodiment. Specifically, FIG. 6 shows a cross section taken along line VI-VI shown in FIG. 5. FIG. 7 shows a cross section taken along line VII-VII shown in FIG. 5.

Semiconductor device for power amplification 1 shown in FIG. 1 to FIG. 4 is a HEMT that is formed using a GaN (gallium nitride) semiconductor material, and may be referred to as a GaN HEMT. The GaN semiconductor material is a semiconductor material that contains Ga (gallium) and N (nitride). The GaN semiconductor material may contain, for example, Al (aluminum) and In (indium) other than Ga and N. The GaN semiconductor material is characterized by a large band gap, a high insulation breakdown electric field strength, and a high saturated drift velocity. For this reason, the GaN HEMT is capable of achieving properties such as a low on resistance, a high breakdown voltage, and a high switching speed.

Semiconductor device for power amplification 1 according to the embodiment is used as, for example, a high-frequency transistor. For example, semiconductor device for power amplification 1 is applicable to a mobile phone and a power amplifier of a communication device included in a base station etc.

Semiconductor device for power amplification 1 has a configuration in which single unit portions of a transistor are repeatedly arranged in a matrix in a two-dimensional plane (specifically an XY plane). A single unit portion of the transistor is a portion that includes unit channel region 90, gate electrode 40, drain electrode 50, and unit source region 92 (specifically source electrode 60, source via 70, etc.) shown in FIG. 5, and means the smallest unit operable as the transistor.

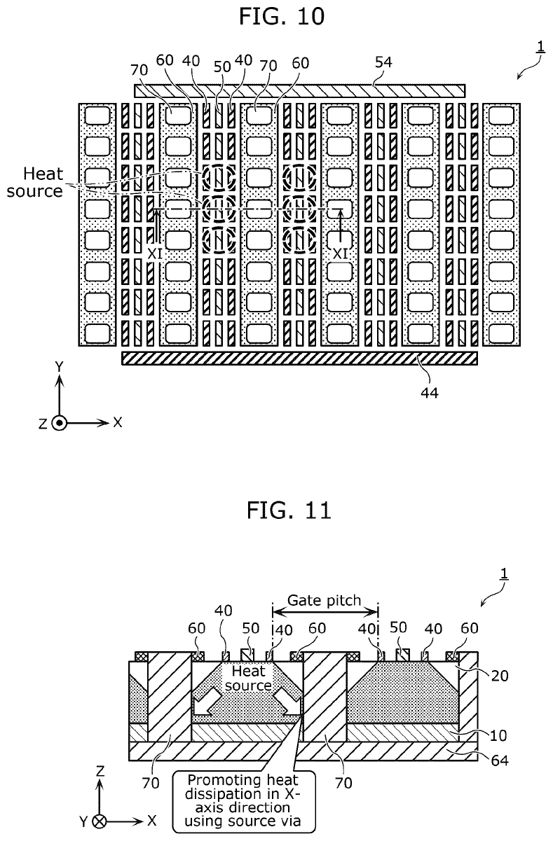

As shown in FIG. 1 to FIG. 4, semiconductor device for power amplification 1 includes substrate 10, semiconductor layer 20, gate electrode 40, gate finger 42, gate bus 44, drain electrode 50, drain finger 52, drain bus 54 (see FIG. 10), source electrode 60, source connector 62, lower electrode 64, source via 70, field plate 80, and plate drive line 82. Semiconductor layer 20 is divided into isolation region 30 and active region 31 in a plan view. A plurality of gate electrodes 40, a plurality of gate fingers 42, a plurality of drain electrodes 50, a plurality of drain fingers 52, a plurality of source electrodes 60, a plurality of source vias 70, a plurality of field plates 80, and a plurality of plate drive lines 82 are provided.

Substrate 10 is a Si (silicon) substrate, but is not limited to this example. Substrate 10 may be a sapphire substrate, a SiC (silicon carbon) substrate, or a GaN substrate.

Semiconductor layer 20 is provided above substrate 10 and includes a plurality of active layers that comprise group-III nitride. The group-III nitride is, for example, GaN nitride. Two-dimensional electron gas 22 is produced in a hetero interface of the plurality of active layers. It should be noted that two-dimensional electron gas 22 is schematically indicated by the dashed line in FIG. 2.

The plurality of active layers are, for example, two GaN semiconductor layers each of which has a different band gap. As shown in FIG. 6 and FIG. 7, specifically, the two GaN semiconductor layers are GaN layer 24 and AlGaN layer 26. GaN layer 24 and AlGaN layer 26 are stacked in stated order from a substrate 10 side. Two-dimensional electron gas 22 is produced in a hetero interface between AlGaN layer 24 having a large band gap and GaN layer 24 having a small band gap. In the plan view, semiconductor layer 20 is divided into active region 31 that contains two-dimensional electron gas 22, and isolation region 30 that does not contain two-dimensional electron gas 22.

Semiconductor layer 20 includes a channel region that contains at least part of two-dimensional electron gas 22. The channel region is an overlapping portion of active region 31 and the plurality of gate electrodes 40 in the plan view. The channel region is a portion of a current pathway between drain electrode 50 and source electrode 60 in semiconductor device for power amplification 1, and is a region the conduction and non-conduction of which is controlled by gate electrode 40. The channel region includes a plurality of unit channel regions 90 that are separated by isolation region 30 and arranged in the X-axis direction.

It should be noted that semiconductor layer 20 may include a layer other than the plurality of active layers. For example, the layer other than the plurality of active layers is a layer that comprises GaN, AlGaN, InGaN, InAlGaN, AlN, or InN, etc. For example, semiconductor layer 20 may include a buffer layer disposed between substrate 10 and GaN layer 24. Such a buffer layer makes it possible to improve the film quality of GaN layer 24 and AlGaN layer 26. Each layer included in semiconductor layer 20 is formed by an epitaxial growth method.

Isolation region 30 is a region not containing two-dimensional electron gas 22. Isolation region 30 separates the channel region of semiconductor layer 20 into the plurality of unit channel regions 90 that are arranged in the Y-axis direction. A unit channel region may be referred to as a separated channel region. As shown in FIG. 5 and FIG. 6, unit channel region 90 is a region overlapping gate electrode 40 in the plan view, that is, a region immediately below gate electrode 40. Gate length Lg (see FIG. 6) that is the length of gate electrode 40 in the X-axis direction corresponds to the length of unit channel region 90 in the X-axis direction. In FIG. 5, the outline of unit channel region 90 is indicated by the thick long dashed line.

Isolation region 30 is formed in a region that includes at least a hetero interface between GaN layer 24 and AlGaN layer 26 that have been epitaxially grown, that is, a region in which two-dimensional electron gas 22 is produced. Isolation region 30 is formed by inactivating a portion of semiconductor layer 20 by ion implantation. For example, isolation region 30 is formed by implanting ions of Ar (argon), B (boron), He (helium), etc. into the region including at least the hetero interface between GaN layer 24 and AlGaN layer 26 that have been epitaxially grown. Two-dimensional electron gas 22 is not produced in isolation region 30.

Alternatively, isolation region 30 may be formed by removing, by etching, GaN layer 24 and AlGaN layer 26 that have been epitaxially grown, to at least a depth at which two-dimensional electron gas 22 is produced. For example, isolation region 30 may be an insulating layer formed in a portion removed from GaN layer 24 and AlGaN layer 26.

Gate electrode 40 is spaced apart from source electrode 60 and drain electrode 50, and is in contact with semiconductor layer 20. In addition, gate electrode 40 is electrically connected to gate finger 42, and is disposed between gate finger 42 and semiconductor layer 20. Specifically, gate electrode 40 is an electrode in Schottky contact with semiconductor layer 20. Gate electrode 40 is a control electrode of semiconductor device for power amplification 1. Specifically, semiconductor device for power amplification 1 is capable of switching between conduction and non-conduction of unit channel region 90 according to a gate electric potential applied to gate electrode 40 via gate finger 42. When semiconductor device for power amplification 1 is operating, for example, a gate electric potential ranging from −1.5 V to approximately −3 V is applied to gate electrode 40. It should be noted that the magnitude of a gate electric potential is not particularly limited as long as the gate electric potential enables semiconductor device for power amplification 1 to operate.

In the present embodiment, the plurality of gate electrodes 40 are linearly arranged in the Y-axis direction. Each of the plurality of gate electrodes 40 is in an elongated shape in the Y-axis direction and lies on a straight line in the Y-axis direction. In other words, the plurality of gate electrodes 40 are obtained by separating one long gate electrode that extends in the Y-axis direction into a plurality of gate electrodes that are spaced apart. For this reason, gate electrode 40 can be also referred to as a separated gate electrode or a unit gate electrode.

Moreover, the plurality of gate electrodes 40 are provided for each gate finger 42. To put it another way, the plurality of gate electrodes 40 are arranged not only in the Y-axis direction but also in the X-axis direction. In short, gate electrodes 40 are repeatedly arranged in a matrix in a two-dimensional plane (specifically an XY plane).

Gate electrode 40 is formed using a conductive material. For example, gate electrode 40 is a single layer or a stack that comprises a metal, an alloy, or conductive metal nitride. Examples of the metal include Ti (titanium), Ta (tantalum), W (tungsten), Ni (nickel), Pd (palladium), Au (gold), and Al. Examples of the conductive metal nitride include TiN and TaN. Gate electrode 40 is formed in a prescribed shape by, for example, film formation by vapor deposition, sputtering, etc. and patterning by etching etc.

Gate finger 42 is provided above semiconductor layer 20 and extends in the Y-axis direction. Gate finger 42 is provided above the plurality of gate electrodes 40 linearly arranged in the Y-axis direction, and is in contact with and covers all of the plurality of gate electrodes 40. In the present embodiment, as shown in FIG. 3, gate finger 42 is provided above and apart from plate drive line 82. Gate finger 42 is a line for supplying a gate electric potential to gate electrode 40. Gate finger 42 can be referred to as a gate drive line for driving gate electrode 40.

Gate finger 42 has, for example, a cross-sectional area of an XZ cross section larger than that of gate electrode 40. For example, as shown in FIG. 5 and FIG. 6, gate finger 42 has a length in the X-axis direction greater than that of gate electrode 40 in the X-axis direction. Accordingly, it is possible to reduce gate resistance Rg. For example, it is possible to reduce a variation in gate electric potential in a plane, and stabilize transistor operation.

Gate finger 42 is formed using a conductive material. For example, gate finger 42 may be formed using a material having a conductivity higher than that of the material of gate electrode 40. Accordingly, it is possible to further reduce gate resistance Rg. As an example, gate finger 42 is formed using Al, Au, or Cu (copper). Gate finger 42 is formed in a prescribed shape by, for example, film formation by vapor deposition, sputtering, etc. and patterning by etching etc.

In the present embodiment, the plurality of gate fingers 42 are arranged in the X-axis direction and supplied with the same electric potential. For example, the plurality of gate fingers 42 are parallel to each other and arranged at prescribed intervals. As an example, the plurality of gate fingers 42 are arranged to cause gate pitches (see FIG. 11) to be equal. An end portion of each of the plurality of gate fingers 42 on a negative side of the Y-axis direction is connected to gate bus 44.

Gate bus 44 is an integrating line that integrates the plurality of gate fingers 42 and extends in the X-axis direction. Gate bus 44 may be integrally formed using the same material as the material of the plurality of gate fingers 42. Gate bus 44 is formed in a prescribed shape by, for example, film formation by vapor deposition, sputtering, etc. and patterning by etching etc.

Although gate bus 44 is provided on the negative side of the Y-axis direction in the present embodiment, gate bus 44 may be provided on a positive side of the Y-axis direction or on both the positive and negative sides of the Y-axis direction.

Drain electrode 50 is provided above semiconductor layer 20, and is electrically connected to two-dimensional electron gas 22. In addition, drain electrode 50 is electrically connected to drain finger 52, and is disposed between drain finger 52 and semiconductor layer 20. Specifically, drain electrode 50 is an electrode that is ohmic connected to two-dimensional electron gas 22 of semiconductor layer 20. A drain electric potential is supplied to drain electrode 50 via drain finger 52. When semiconductor device for power amplification 1 is operating, for example, a drain electric potential of approximately 150 V at most may be applied to drain electrode 50. It should be noted that the magnitude of a drain electric potential is not particularly limited as long as the drain electric potential enables semiconductor device for power amplification 1 to operate.

In the present embodiment, the plurality of drain electrodes 50 are linearly arranged in the Y-axis direction. Each of the plurality of drain electrodes 50 is in an elongated shape in the Y-axis direction and lies on a straight line in the Y-axis direction. In other words, the plurality of drain electrodes 50 are obtained by separating one long drain electrode that extends in the Y-axis direction into a plurality of drain electrodes that are spaced apart. For this reason, drain electrode 50 can be also referred to as a separated drain electrode or a unit drain electrode.

Moreover, the plurality of drain electrodes 50 are provided for each drain finger 52. To put it another way, the plurality of drain electrodes 50 are arranged not only in the Y-axis direction but also in the X-axis direction. In short, drain electrodes 50 are repeatedly arranged in a matrix in a two-dimensional plane (specifically the XY plane).

Drain electrode 50 is formed using a conductive material. For example, drain electrode 50 is a single layer or a stack that comprises a metal or an alloy. Examples of the metal include Ti, Al, and Au. Drain electrode 50 is formed in a prescribed shape by, for example, film formation by vapor deposition, sputtering, etc. and patterning by etching etc.

Drain finger 52 is provided above semiconductor layer 20 and extends in the Y-axis direction. Drain finger 52 is provided above the plurality of drain electrodes 50 linearly arranged in the Y-axis direction, and is in contact with and covers all of the plurality of drain electrodes 50. Drain finger 52 is a line for supplying a drain electric potential to drain electrode 50. To put it another way, drain finger 52 can be referred to as a drain drive line for driving drain electrode 50.

Drain finger 52 has, for example, a cross-sectional area of an XZ cross section larger than that of drain electrode 50. For example, as shown in FIG. 5 and FIG. 6, drain finger 52 has a length in the X-axis direction greater than that of drain electrode 50 in the X-axis direction. Accordingly, it is possible to reduce drain resistance Rd. For example, it is possible to reduce a variation in drain electric potential in a plane, and stabilize transistor operation.

Drain finger 52 is formed using a conductive material. For example, drain finger 52 may be formed using a material having a conductivity higher than that of the material of drain electrode 50. Accordingly, it is possible to further reduce drain resistance Rd. As an example, drain finger 52 is formed using Al, Au, or Cu. Drain finger 52 is formed in a prescribed shape by, for example, film formation by vapor deposition, sputtering, etc. and patterning by etching etc.

In the present embodiment, the plurality of drain fingers 52 are arranged in the X-axis direction and supplied with the same electric potential. For example, the plurality of drain fingers 52 are parallel to each other and arranged at regular intervals. An end portion of each of the plurality of drain fingers 52 on the positive side of the Y-axis direction is connected to drain bus 54 (see FIG. 10).

Drain bus 54 shown in FIG. 10 is an integrating line that integrates the plurality of drain fingers 52 (not shown in FIG. 10) and extends in the X-axis direction. Drain bus 54 may be integrally formed using the same material as the material of the plurality of drain fingers 52. Drain bus 54 is formed by, for example, plating in the same process as a process for metal filler 72 of source via 70. Alternatively, drain but 54 may be formed in a process different from the process for metal filler 72, and may be formed in a prescribed shape by, for example, film formation by vapor deposition, sputtering, etc. and patterning by etching etc.

Although drain bus 54 is provided on the positive side of the Y-axis direction in the present embodiment, drain bus 54 may be provided on the negative side of the Y-axis direction or on both the positive and negative sides of the Y-axis direction. Drain but 54 may be provided on the same side as gate bus 44.

Source electrode 60 is provided above semiconductor layer 20, spaced apart from drain electrode 50, and electrically connected to two-dimensional electron gas 22. Source electrode 60 is disposed to sandwich gate electrode 40 between source electrode 60 and drain electrode 50. Specifically, source electrode 60 is an electrode that is ohmic connected to two-dimensional electron gas 22 of semiconductor layer 20. A source electric potential is supplied to source electrode 60 via lower electrode 64, source via 70, and source connector 62. A source electric potential is, for example, an electric potential lower than a drain electric potential. When semiconductor device for power amplification 1 is operating, for example, a source electric potential of 0 V is applied to source electrode 60. It should be noted that the magnitude of a source electric potential is not particularly limited as long as the source electric potential enables semiconductor device for power amplification 1 to operate.

In the present embodiment, the plurality of source electrodes 60 are arranged in the Y-axis direction. Each of the plurality of source electrodes 60 is in an elongated shape in the Y-axis direction and lies on a straight line in the Y-axis direction. In other words, the plurality of source electrodes 60 are obtained by separating one long source electrode that extends in the Y-axis direction into a plurality of source electrodes that are spaced apart. For this reason, source electrode 60 can be also referred to as a separated source electrode or a unit source electrode.

The plurality of source electrodes 60 are provided for each unit channel region 90. Specifically, source electrode 60 is provided for each unit source region 92 that faces unit channel region 90. In the present embodiment, the plurality of source electrodes 60 are arranged not only in the Y-axis direction but also in the X-axis direction. In short, source electrodes 60 are repeatedly arranged in a matrix in a two-dimensional plane (specifically the XY plane).

Here, the term “face” means being located in front when a direction from unit channel region 90 parallel to a gate length direction, that is, the X-axis direction is viewed. Specifically, the length and position of unit source region 92 in the Y-axis direction correspond with the length and position of unit channel region 90 in the Y-axis direction. Respective portions of the outline of unit source region 92 on a positive side and a negative side of the X-axis direction are defined by a portion of the outline of source electrode 60 on the positive side of the X-axis direction and a portion of the outline of one of source via 70 or source connector 62 located on the most negative side of the X-axis direction. For example, unit source region 92 is defined as a rectangular region as indicated by the thick dash-double-dot line in FIG. 5.

Source electrode 60 is formed using a conductive material. For example, source electrode 60 is a single layer or a stack that comprises a metal or an alloy. Examples of the metal include Ti, Al, and Au. Source electrode 60 is formed in a prescribed shape by, for example, film formation by vapor deposition, sputtering, etc. and patterning by etching etc. It is possible to form source electrode 60 using the same material as the material of drain electrode 50 in the same process as a process for drain electrode 50.

It should be noted source electrode 60 may be provided across isolation region 30 from semiconductor layer 20. In other words, a portion of source electrode 60 may be provided above isolation region 30.

Source connector 62 is provided to connect the plurality of source electrodes 60. Source connector 62 is a line for supplying a source electric potential to source electrode 60. Source connector 62 can be referred to as a source drive line for driving source electrode 60.

In the present embodiment, as shown in FIG. 1, source connector 62 extends in the Y-axis direction and covers the plurality of source vias 70, at least some of the plurality of source electrodes 60, and some of the plurality of plate drive lines 82. As shown in FIG. 2 and FIG. 3, source connector 62 is in contact with part of the top faces of the plurality of source electrodes 60 and part of the top faces of the plurality of plate drive lines 82, and is electrically conducted.

In the plan view, source connector 62 includes a portion that overlaps source via 70, and a portion that does not overlap source via 70. In this case, the portion overlapping source via 70 in the plan view is regarded as an upper portion higher than the top face of metal coating 74 of source via 70. It should be noted that when source via 70 does not include metal coating 74, a portion overlapping source via 70 in the plan view is regarded as an upper portion higher than the top face of isolation region 30.

It should be noted that source connector 62 may be provided to enable electrical conduction between (i) the plurality of source vias 70 and (ii) the plurality of source electrodes 60 and the plurality of plate drive lines 82. For example, in the plan view, source connector 62 may be provided in contact with a portion of a lateral face of source via 70, a portion of a lateral face of source electrode 60, and a portion of a lateral face of plate drive line 82, without overlapping any of source via 70, source electrode 60, and plate drive line 82. It should be noted that when source electrode 60 and plate drive line 82 are electrically conducted by being in contact with each other, source connector 62 may be in contact with one of source electrode 60 or plate drive line 82, and need not be in contact with the other of source electrode 60 or plate drive line 82.

Source connector 62 is formed using a conductive material. For example, source connector 62 is a single layer or a stack that comprises a metal or an alloy. Examples of the metal include Ti, Al, and Au. It is possible to form source connector 62 by, for example, plating, using the same material as the material of metal filler 72 of source via 70 in the same process as the process for metal filler 72 of source via 70. Alternatively, source connector 62 may be formed using the same material as the material of source electrode 60 or metal coating 74 of source via 70 in the same process as a process for source electrode 60 or metal coating 74. For example, source connector 62 may be formed in a prescribed shape by, for example, film formation by vapor deposition, sputtering, etc. and patterning by etching etc.

Lower electrode 64 is provided below substrate 10. Lower electrode 64 may be also referred to as a back source electrode. Specifically, lower electrode 64 is provided on the entire bottom face of substrate 10. Lower electrode 64 is supplied with the same electric potential as an electric potential supplied to source electrode 60. Specifically, lower electrode 64 is connected to source via 70 and supplies a source electric potential to each of the plurality of source electrodes 60 via source via 70 and source connector 62.

Lower electrode 64 is formed using a conductive material. For example, lower electrode 64 is a single layer or a stack that comprises a metal or an alloy. Examples of the metal include Au, Sn (tin), and Ag (silver). It should be noted that semiconductor device for power amplification 1 is mounted on, for example, a submount substrate using silver paste, solder, or a metal bonding material, etc. Lower electrode 64 also serves as a connecting electrode for the submount substrate etc.

Source via 70 includes a conductor that penetrates through substrate 10 and semiconductor layer 20 and is in contact with lower electrode 64. Source via 70 electrically connects lower electrode 64 and source electrode 60. Source via 70 is provided in at least one of the plurality of unit source regions 92. In the present embodiment, source via 70 and unit source region 92 are provided on a one-to-one basis. In other words, one source via 70 is provided in each of the plurality of unit source regions 92. To put it another way, the number of at least one source via 70 included in unit source region 92 is one. Only one source via 70 provided in one unit source region 92 can be referred to as a single source via.

Source via 70 includes a conductor that is filled in via hole 71 that penetrates through semiconductor layer 20 and isolation region 30. As shown in FIG. 1 and FIG. 2, source via 70 includes metal filler 72 and metal coating 74. Metal filler 72 and metal coating 74 each are an example of the conductor in contact with lower electrode 64.

Metal filler 72 is a conductive component that fills via hole 71. Metal filler 72 is also referred to as a filled via. In the present embodiment, metal filler 72 is provided to completely fill via hole 71.

Metal coating 74 is a conductive thin film that is in contact with and covers a lateral face of via hole 71. As shown in FIG. 2 and FIG. 3, metal coating 74 further covers the top face of each of semiconductor layer 20 and isolation region 30 in an edge portion of an opening of via hole 71. Metal coating 74 is also referred to as a lined via. It should be noted that although the cross section (an XZ cross section cutting through plate drive line 82) shown in FIG. 3 shows an example in which only metal coating 74 is provided in via hole 71, the present disclosure is not limited to this example. As with FIG. 2, metal filler 72 may be provided in the XZ cross section cutting through plate drive line 82.

Source via 70 is formed by, for example, forming metal coating 74 and metal filler 72 in stated order by plating etc. after via hole 71 is formed by etching etc. Via hole 71 may be formed from a top face side or a bottom face side of substrate 10.

Moreover, source via 70 may include only one of metal filler 72 or metal coating 74. In other words, filling with a metal material need not be performed after metal coating 74 is formed in via hole 71. Alternatively, filling with a metal material may be performed to form metal filler 72 without forming metal coating 74 in via hole 71.

Field plate 80 is provided above semiconductor layer 20 and between gate electrode 40 and drain electrode 50 in the plan view. Field plate 80 is supplied with the same electric potential as the electric potential supplied to source electrode 60. Field plate 80 is provided to mitigate an electric field between gate electrode 40 and drain electrode 50 by being fixed to a source electric potential.

In the present embodiment, field plate 80 includes a plurality of unit plates 81 that face the plurality of unit channel regions 90. The plurality of unit plates 81 can be each referred to as a separated field plate electrode into which field plate 80 is separated. In the present embodiment, as shown in FIG. 1 and FIG. 5, unit plate 81 does not overlap gate finger 42 in the plan view, but the present disclosure is not limited to this example. A portion of unit plate 81 may overlap gate finger 42 in the plan view.

Field plate 80 is formed using a conductive material. For example, field plate 80 is a single layer or a stack that comprises a metal or an alloy. Examples of the metal include Al, Au, or Cu. Field plate 80 is formed in a prescribed shape by, for example, film formation by vapor deposition, sputtering, etc. and patterning by etching etc.

Plate drive line 82 is a line for suppling a source electric potential to field plate 80. At least one plate drive line 82 is provided for each unit plate 81. In the present embodiment, as shown in FIG. 5 and FIG. 7, two plate drive lines 82 are provided for each unit plate 81. Two plate drive lines 82 are connected to the both end portions of unit plate 81 in the Y-axis direction.

Plate drive line 82 extends from a corresponding source electrode 60 side in the X-axis direction, and is connected to corresponding unit plate 81. Plate drive line 82 electrically connects corresponding unit plate 81 and source connector 62. Plate drive line 82 supplies a source electric potential to each of the plurality of unit plates 81. As shown in FIG. 3, plate drive line 82 is in contact with metal coating 74 and source connector 62 at an end portion on a source via 70 side. Since area of contact between source connector 62 and plate drive line 82 increases by source connector 62 being in contact with the top face of plate drive line 82, it is possible to reduce contact resistance. Accordingly, it is possible to stabilize the source electric potential of field plate 80, that is, the plurality of unit plates 81.

Plate drive line 82 is provided within isolation region 30 in the plan view. Specifically, plate drive line 82 is provided above isolation region 30. In the present embodiment, as shown in FIG. 3 and FIG. 7, plate drive line 82 is in contact with isolation region 30.

Plate drive line 82 extends in the X-axis direction. As shown in FIG. 3, plate drive line 82 is provided to rise toward a positive side of the Z-axis direction at an end portion on a drain finger 52 side, and is connected to unit plate 81 of field plate 80 at a tip portion on the positive side of the Z-axis direction.

Field drive line 82 is formed using a conductive material. For example, plate drive line 82 is a single layer or a stack that comprises a metal or an alloy. Plate drive line 82 may be formed using the same material as the material of field plate 80. Plate drive line 82 is formed in a prescribed shape by, for example, film formation by vapor deposition, sputtering, etc. and patterning by etching etc. [2. Characteristic Configuration, Advantageous Effects, etc.]

Subsequently, a characteristic configuration, advantageous effects, etc. of semiconductor device for power amplification 1 according to the present embodiment are described by comparing with a comparative example.

### 2-1. Configuration of and Problems with Comparative Example

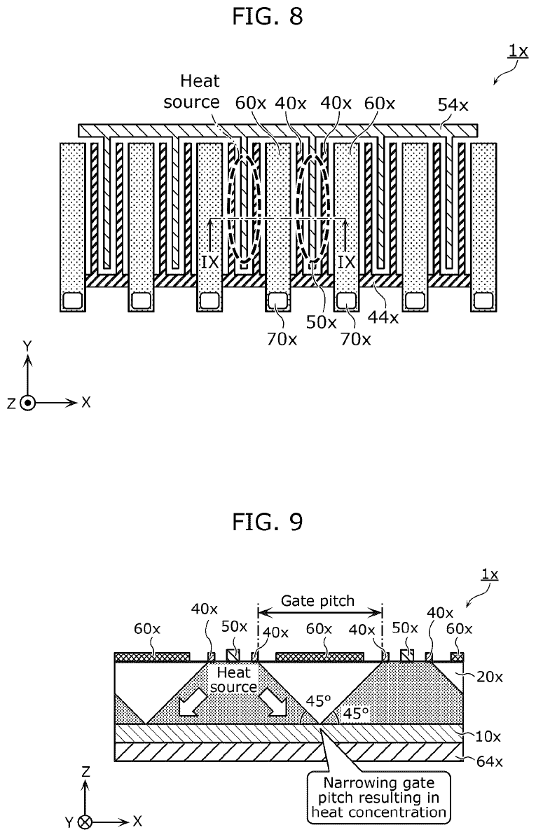

First, a configuration of and problems with a semiconductor device for power amplification according to the comparative example are described with reference to FIG. 8 and FIG. 9. FIG. 8 and FIG. 9 are a plan view and a cross-sectional view of semiconductor device for power amplification 1x according to the comparative example, respectively. FIG. 9 shows a cross section taken along line IX-IX shown in FIG. 8.

As shown in FIG. 8 and FIG. 9, semiconductor device for power amplification 1x according to the comparative example includes substrate 10x, semiconductor layer 20x, gate electrode 40x, gate bus 44x, drain electrode 50x, drain bus 54x, source electrode 60x, lower electrode 64x, and source via 70x. Substrate 10x, semiconductor layer 20x, gate bus 44x, drain bus 54x, and lower electrode 64x are the same as substrate 10, semiconductor layer 20, gate bus 44, drain bus 54, and lower electrode 64 included in semiconductor device for power amplification 1 according to the embodiment.

In semiconductor device for power amplification 1x according to the comparative example, as shown in FIG. 8, both gate electrode 40x and drain electrode 50x extend in the Y-axis direction and are not separated. In other words, gate electrode 40x and drain electrode 50x have the same configuration as the configurations of gate finger 42 and drain finger 52 of semiconductor device for power amplification 1 according to the embodiment.

Moreover, isolation region 30 is not provided in semiconductor device for power amplification 1x according to the comparative example. To put it another way, a channel region of semiconductor layer 20x is not separated into a plurality of unit channel regions 90.

Furthermore, source electrode 60x also extends in the Y-axis direction and is not separated. One source via 70x is provided in an end portion of each source electrode 60x on the negative side of the Y-axis direction.

In semiconductor device for power amplification 1x, the channel region and an area in the vicinity of the channel region are a heat source. Specifically, the heat source can be regarded as a region from immediately below each gate electrode 40x toward drain electrode 50x. In FIG. 8, the heat source is indicated by the thick dashed line. A region immediately below between two drain electrodes 50x sandwiching gate electrode 40x is the heat source.

In FIG. 9, spread of heat from the heat source is schematically indicated by dot hatching and open arrows. After diffused into semiconductor layer 20x, heat generated spreads in a lateral direction (the X-axis direction and the Y-axis direction) through substrate 10x and lower electrode 64x. The heat having reached lower electrode 64x is released to the outside through a submount substrate (not shown in the figure) on which semiconductor device for power amplification 1x is mounted.

When heat generated in the vicinity of gate electrode 40x diffuses in semiconductor layer 20x in the thickness direction (the Z-axis direction), the heat also spreads in the lateral direction (the X-axis direction and the Y-axis direction). The spread angle of the heat can be schematically regarded as 45 degrees. Since gate electrodes 40x are arranged in the X-axis direction, when heat generated in the vicinity of one of two adjacent gate electrodes 40x overlaps heat generated in the vicinity of an other of two adjacent gate electrodes 40x before reaching substrate 10x, a region that has a high temperature locally is created. For this reason, it is necessary to leave a large space (referred to as a gate pitch) between gate electrodes 40x in the X-axis direction. It should be noted that, in FIG. 9, the gate pitch is a distance (a distance in the X-axis direction) between two gate electrodes 40x that are adjacent to sandwich source electrode 60x without sandwiching drain electrode 50x.

From the above, in semiconductor device for power amplification 1x according to the comparative example, a plurality of gate electrodes 40x are arranged with a large gate pitch left therebetween, and the length of gate bus 44x in the X-axis direction is increased. Since increasing gate bus 44x in length results in an increase in gate resistance Rg and parasitic inductance components, the high-frequency property of semiconductor device for power amplification 1x is degraded. For example, the gain, efficiency, and saturation power of semiconductor device for power amplification 1x are each decreased.

Moreover, source via 70x is provided in the end portion on the negative side of the Y-axis direction, and a source electric potential is supplied to source electrode 60x from an off-center position. For this reason, since a variation in source electric potential is more likely to occur in a plane, and there is a possibility that the transistor operation of semiconductor device for power amplification 1x becomes unstable.

Furthermore, when a field plate is disposed between gate electrode 40x and drain electrode 50x, a source electric potential supplied to the field plate also becomes unstable. Since an impedance of a portion of the field plate away from a power feeder becomes higher, electric potential fixing by the field plate is weakened. For this reason, it may not be possible to sufficiently mitigate an electric field between gate electrode 40x and drain electrode 50x, and the properties and reliability of semiconductor device for power amplification 1x are degraded.

In order to reduce a variation in source electric potential, it is necessary to control the length of source electrode 60x in the Y-axis direction. In this case, since a gate width (a channel width) is decreased, in order to ensure a necessary amount of drain current, it is necessary to increase the number of sets of gate electrode 40x, drain electrode 50x, and source 60x. As a result, the length of gate bus 44x in the X-axis direction is increased, and, as stated above, the high-frequency property of semiconductor device for power amplification 1x is degraded.

Although the details are described later in the description of advantageous effects etc. of source via 70, it is possible to cause source via 70x to contribute to heat dissipation. In semiconductor device for power amplification 1x, however, since source via 70x is provided in an off-center position, it is hardly possible to cause source via 70x to contribute to the improvement of heat dissipation performance.

With regard to the above problems, it is intended to improve the high frequency property of semiconductor device for power amplification 1 according to the present embodiment by disposing the plurality of unit channel regions 90, the plurality of source vias 70 each of which is elongated in the X-axis direction, and the plurality of plate drive lines 82 that extend in the X-axis direction in semiconductor device for power amplification 1. It should be noted that at least one of source via 70 or plate drive line 82 is not an essential element in the present embodiment. Hereinafter, advantageous effects achieved by each of unit channel region 90, source via 70, and plate drive line 82 are described in detail.

### 2-2. Unit Channel Region

First, the advantageous effects etc. achieved by unit channel region 90 are described with reference to FIG. 10. FIG. 10 is a plan view of an example of application of the semiconductor device for power amplification according to the embodiment.

In semiconductor device for power amplification 1 according to the present embodiment, unit channel region 90 and an area in the vicinity of unit channel region 90 are a heat source. Specifically, the heat source can be regarded as a region from immediately below gate electrode 40 toward drain electrode 50. For the sake of easy-to-understand explanation, unit channel region 90 may be regarded as the heat source in what follows.

In the present embodiment, the plurality of unit channel regions 90 correspond to the plurality of gate electrodes 40 on a one-to-one basis, and are arranged in the Y-axis direction. In the Y-axis direction, isolation region 30 that does not serve as a channel, that is, does not become a current pathway is provided between two adjacent unit channel regions 90. For this reason, as indicated by the thick dashed lines in FIG. 10, heat sources are separately disposed. Since the heat sources are separately disposed in the Y-axis direction, it is possible to efficiently diffuse heat using a region (specifically, isolation region 30) between adjacent heat sources. In other words, it is possible to reduce thermal resistance in the Y-axis direction, and improve the heat dissipation performance of semiconductor device for power amplification 1. Since the heat dissipation performance is improved, it is possible to reduce the property degradation due to heat.

### 2-3. Source Via

Subsequently, the advantageous effects etc. achieved by source via 70 are described with reference to FIG. 10 and FIG. 11. FIG. 11 is a cross-sectional view of an example of application of the semiconductor device for power amplification according to the embodiment. Specifically, FIG. 11 shows a cross section taken along line XI-XI shown in FIG. 10.

Source via 70 is provided in unit source region 92 (see FIG. 5) that faces unit channel region 90. In other words, source via 70 is disposed in an immediate vicinity of the heat source. To put it simply, source via 70 is disposed in a position at which a distance from the heat source is shortest in the X-axis direction. As shown in FIG. 11, heat that spreads in the X-axis direction reaches source via 70 before reaching substrate 10. Source via 70 is formed using metal and has a heat conductivity higher than that of semiconductor layer 20. For this reason, since the heat is efficiently conducted to substrate 10 and lower electrode 64 through source via 70, it is possible to improve the heat dissipation performance of semiconductor device for power amplification 1.

As a result, since it is possible to narrow a gate pitch, it is possible to decrease the length of gate bus 44 in the X-axis direction. It should be noted that the “gate pitch” is a distance (a distance in the X-axis direction) between two gate electrodes 40 that are adjacent to sandwich source electrode 60 without sandwiching drain electrode 50.

Accordingly, it is possible to reduce gate resistance Rg and parasitic inductance components, and reduce the degradation of the high-frequency property of semiconductor device for power amplification 1. For example, it is possible to reduce a decrease in gain, efficiency, and saturation power of semiconductor device for power amplification 1.

Moreover, as shown in FIG. 5, in the plan view, source via 70 is in an elongated shape in the X-axis direction. In other words, Lvx<Lvy is satisfied, where the length of source via 70 in the X-axis direction is denoted by Lvx, and the length of source via 70 in the Y-axis direction is denoted by Lvy. Accordingly, it is possible to promote the spread of heat conducted from unit channel region 90 in the X-axis direction, and improve the heat dissipation performance. It should be noted that the length of source via 70 in the X-axis direction is the length of an opening outline of source via 70 in the X-axis direction. The length of the opening outline in the X-axis direction is equivalent to the maximum distance of an opening outline of via hole 71 on a semiconductor layer 20 side in the X-axis direction, via hole 71 being for filling the conductor (metal filler 72 and metal coating 74) of source via 70. The same applies to the Y-axis direction. To put it another way, the expression “the length of an outline in a direction” indicates not a length along the outline but a linear distance in the direction.

Furthermore, as shown in FIG. 5, in the Y-axis direction, the length of the opening outline of source via 70 is greater than the length of corresponding unit source region 92. In other words, source via 70 is also located outside unit source region 92. Stated differently, source via 70 protrudes from unit source region 92 in the Y-axis direction.

Specifically, Lvy>Lcy is satisfied, where the length of unit channel region 90 in the Y-axis direction is denoted by Lcy. In other words, source via 70 that is greater in width than the heat source is disposed close to the heat source. For this reason, source via 70 makes it possible to efficiently dissipate heat that spreads in the Y-axis direction included in heat generated in unit channel region 90.

In the present embodiment, source via 70 is provided to correspond to unit channel region 90 on a one-to-one basis. In other words, one source via 70 is provided for each of a plurality of heat sources. For this reason, since source vias 70 are provided evenly in a plane, it is possible to reduce the aggravation of local heat dissipation performance. Accordingly, it is possible to improve the heat dissipation performance of semiconductor device for power amplification 1.

Moreover, it is possible to supply a source electric potential to each of the plurality of source electrodes 60 in substantially the shortest distance from lower electrode 64. Accordingly, it is possible to stabilize the source electric potential of each of the plurality of source electrodes 60. In addition, since it is possible to reduce parasitic inductance components, it is possible to reduce high-frequency loss.

As stated above, semiconductor device for power amplification 1 according to the present embodiment includes: substrate 10; lower electrode 64 provided below substrate 10; semiconductor layer 20 that is provided above substrate 10 and includes a plurality of active layers comprising group-III nitride, and in which two-dimensional electron gas 22 is produced in a hetero interface of the plurality of active layers; source electrode 60 and drain electrode 50 that are provided above semiconductor layer 20, spaced apart from each other, and electrically connected to two-dimensional electron gas 22; gate electrode 40 that is spaced apart from source electrode 60 and drain electrode 50 and is in contact with semiconductor layer 20; gate finger 42 that is in contact with and covers all of a plurality of gate electrodes 40 arranged linearly in a Y-axis direction, the plurality of gate electrodes 40 each being gate electrode 40; and drain finger 52 that is in contact with and covers all of a plurality of drain electrodes 50 arranged linearly in the Y-axis direction, the plurality of drain electrodes 50 each being drain electrode 50. A plurality of gate fingers 42 are arranged in an X-axis direction orthogonal to the Y-axis direction and supplied with a same electric potential, the plurality of gate fingers 42 each being gate finger 42. In a plan view of substrate 10, semiconductor layer 20 is divided into active region 31 containing two-dimensional electron gas 22 and isolation region 30 not containing two-dimensional electron gas 22. In the plan view, a channel region includes a plurality of unit channel regions 90 that are separated by isolation region 30 and arranged in the Y-axis direction, the channel region being an overlapping portion of active region 31 and the plurality of gate electrodes 40. Source electrode 60 includes a plurality of unit source electrodes each of which faces a corresponding one of the plurality of unit channel regions 90. A plurality of unit source regions 92 each include at least one source via 70 that contains a conductor that penetrates through substrate 10 and semiconductor layer 20 and is in contact with lower electrode 64 that is supplied with a same electric potential as an electric potential supplied to source electrode 60, the plurality of unit source regions 92 each including a corresponding one of the plurality of unit source electrodes. In the plan view, a length of a side of a minimum rectangular region in the X-axis direction is greater than a length of a side of the minimum rectangular region in the Y-axis direction, the minimum rectangular region surrounding the at least one source via 70.

Accordingly, since the plurality of unit channel regions 90 are arranged in the Y-axis direction, heat sources are dispersedly disposed in the Y-axis direction, and it is possible to improve heat dissipation performance in the Y-axis direction. Additionally, since source via 70 is disposed in unit source region 92 that faces unit channel region 90, it is also possible to improve heat dissipation performance in the X-axis direction. Consequently, it is possible to improve the heat dissipation performance of semiconductor device for power amplification 1, and reduce property degradation due to heat.

Moreover, it is possible to stabilize a source electric potential of source electrode 60 by disposing source electrode 60 and source via 70 close to each other. In addition, it is possible to reduce parasitic inductance components of a source line. Accordingly, it is possible to reduce high-frequency loss of semiconductor device for power amplification 1.

It should be noted that the number of at least one source via 70 is one in the present embodiment. In the plan view, the length of the opening outline of source via 70 in the X-axis direction is greater than the length of the opening outline of source via 70 in the Y-axis direction. For this reason, the lengths of a minimum rectangular region in the X-axis direction and the Y-axis direction are equal to length Lvx and length Lvy of the opening outline of source via 70 in the X-axis direction and the Y-axis direction shown in FIG. 5, respectively. In consequence, length Lvx of the opening outline of source via 70 in the X-axis direction is greater than length Lvy of the opening outline of source via 70 in the Y-axis direction.

Accordingly, it is possible to further improve the heat dissipation performance in the X-axis direction.

Furthermore, for example, in the Y-axis direction, the length of the opening outline of source via 70 is greater than the length of unit channel region 90.

Accordingly, it is possible to further improve the heat dissipation performance in the Y-axis direction. In addition, since the area of source via 70 is increased, it is possible to contribute to an increase in stability of the source electric potential and the reduction of the parasitic inductance components.

Moreover, for example, at least one source via 70 is provided in each of the plurality of unit source regions 92.

Accordingly, since source vias 70 are disposed in a plane in a balanced manner, it is possible to reduce local heat concentration. Additionally, it is possible to reduce an in-plane variation in source electric potential.

### 2-4. Plate Drive Line

Subsequently, the advantageous effects etc. achieved by plate drive line 82 are described.

As shown in FIG. 5, plate drive line 82 extends in the X-axis direction and electrically connects source electrode 60 and unit plate 81 of field plate 80. At least one plate drive line 82 is provided for each of a plurality of unit plates 81.

As stated above, source electrode 60 is stably supplied with the source electric potential from lower electrode 64 through source via 70 and source connector 62 provided in corresponding unit source region 92. For this reason, plate drive line 82 provided for each unit plate 81 makes it possible to supply a stable source electric potential to unit plate 81. In other words, since a variation in electric potential of unit plate 81 is reduced in the XY plane, it becomes easier to evenly mitigate an electric field between gate electrode 40 and drain electrode 50 in a plane. Accordingly, it is possible to increase the saturation power of semiconductor device for power amplification 1.

Moreover, since the source electric potential is supplied to unit plate 81 from the X-axis direction, it is possible to arrange many unit plates 81 in the Y-axis direction in a state in which the stability of the source electric potential is increased. In other words, it is possible to increase the length of gate finger 42 in the Y-axis direction. As a result, it is possible to decrease the length of gate bus 44 in the X-axis direction, and reduce the number of drain fingers 52. For this reason, since it is possible to reduce capacitance Cds between drain electrode 50 and source electrode 60, it is possible to improve efficiency performance of semiconductor device for power amplification 1.

As stated above, semiconductor device for power amplification 1 according to the present embodiment includes: substrate 10; lower electrode 64 provided below substrate 10; semiconductor layer 20 that is provided above substrate 10 and includes a plurality of active layers comprising group-III nitride, and in which two-dimensional electron gas 22 is produced in a hetero interface of the plurality of active layers; source electrode 60 and drain electrode 50 that are provided above semiconductor layer 20, spaced apart from each other, and electrically connected to two-dimensional electron gas 22; gate electrode 40 that is spaced apart from source electrode 60 and drain electrode 50 and is in contact with semiconductor layer 20; field plate 80 that is provided between gate electrode 40 and drain electrode 50 above semiconductor layer 20 and supplied with a same electric potential as an electric potential supplied to source electrode 60; gate finger 42 that is in contact with and covers all of a plurality of gate electrodes 40 arranged linearly in a Y-axis direction, the plurality of gate electrodes 40 each being gate electrode 40; and drain finger 52 that is in contact with and covers all of a plurality of drain electrodes 50 arranged linearly in the Y-axis direction, the plurality of drain electrodes 50 each being drain electrode 50. In a plan view of substrate 10, semiconductor layer 20 is divided into active region 31 containing two-dimensional electron gas 22 and isolation region 30 not containing two-dimensional electron gas 22. In the plan view, a channel region includes a plurality of unit channel regions 90 that are separated by isolation region 30 and arranged in the Y-axis direction, the channel region being an overlapping portion of active region 31 and the plurality of gate electrodes 40. Source electrode 60 includes a plurality of unit source electrodes each of which faces a corresponding one of the plurality of unit channel regions 90. Field plate 80 includes a plurality of unit plates 81 each of which faces a corresponding one of the plurality of unit channel regions 90. At least one of a plurality of plate drive lines 82 is provided, for each of the plurality of unit plates 81, within isolation region 30, the plurality of plate drive lines 82 extending in an X-axis direction orthogonal to the Y-axis direction and electrically connecting the plurality of unit source electrodes and the plurality of unit plates 81.

Accordingly, since the plurality of unit channel regions 90 are arranged in the Y-axis direction, heat sources are dispersedly disposed in the Y-axis direction, and it is possible to improve heat dissipation performance in the Y-axis direction. Consequently, it is possible to improve the heat dissipation performance of semiconductor device for power amplification 1, and reduce property degradation due to heat.

Furthermore, it is possible to supply a stable source electric potential to each of the plurality of unit plates 81 from the X-axis direction via plate drive line 82. Since it is possible to decrease an impedance of field plate 80 (unit plate 81), and a variation in electric potential of unit plate 81 is reduced in the XY plane, it becomes easier to evenly mitigate an electric field between gate electrode 40 and drain electrode 50 in a plane. Accordingly, it is possible to increase the saturation power of semiconductor device for power amplification 1.

Moreover, since it is possible to arrange many unit plates 81 in the Y-axis direction in a state in which the stability of the source electric potential is increased, it is possible to increase the length of gate finger 42 in the Y-axis direction. For this reason, it is possible to decrease the length of gate bus 44 in the X-axis direction, and reduce the number of drain fingers 52. Since it is possible to reduce capacitance Cds between drain electrode 50 and source electrode 60, it is possible to improve efficiency performance of semiconductor device for power amplification 1.

Furthermore, for example, the plurality of plate drive lines 82 are in contact with isolation region 30.

Accordingly, plate driver line 82 is located close to unit channel region 90, and it is possible to use plate driver line 82 as a path for releasing heat. For this reason, it is possible to improve the heat dissipation performance of semiconductor device for power amplification 1.

Moreover, for example, gate finger 42 is provided above and apart from the plurality of plate drive lines 82.

Accordingly, since it becomes easier to increase a distance between gate finger 42 and plate drive line 82 supplied with the source electric potential, it is possible to reduce gate-source capacitance Cgs. As an example, when plate drive line 82 has a thickness of 0.2 μm, a distance between the bottom face of gate finger 42 and the top face of plate drive line 82 is 0.8 μm. By reducing gate-source capacitance Cgs, it is possible to improve gain performance of semiconductor device for power amplification 1.

Furthermore, by keeping the distance long, for example, it becomes easier to increase the cross-sectional area of gate finger 42. As a result, since it is also possible to reduce gate resistance Rg, for example, it is possible to reduce a variation in gate electric potential in a plane, and stabilize transistor operation.

Moreover, for example, the plurality of unit source regions 92 each include at least one source via 70 that contains a conductor that penetrates through substrate 10 and semiconductor layer 20 and is in contact with lower electrode 64 that is supplied with the same electric potential as an electric potential supplied to source electrode 60, the plurality of unit source regions 92 each including a corresponding one of the plurality of unit source electrodes.

Accordingly, since source via 70 is disposed in unit source region 92 that faces unit channel region 90, it is possible to improve heat dissipation performance in the X-axis direction. Consequently, it is possible to improve the heat dissipation performance of semiconductor device for power amplification 1, and reduce property degradation due to heat.

Furthermore, by disposing source electrode 60, plate drive line 82, and source via 70 close to each other, it is possible to stabilize the source electric potential of source electrode 60 and the source electric potential of each unit plate 81 supplied via plate drive line 82. In addition, it is possible to reduce parasitic inductance components of a source line. Accordingly, it is possible to reduce high-frequency loss of semiconductor device for power amplification 1.

Moreover, for example, unit plate 81 and unit channel region 90 correspond to each other on a one-to-one basis.

Accordingly, since it is possible to reduce a variation in electric field mitigation performance in a plane, it is possible to improve the uniformity of the transistor operation of semiconductor device for power amplification 1.

### 3. Variations

Subsequently, a plurality of variations of semiconductor device for power amplification 1 according to the embodiment are described. The following description focuses mainly on differences from the embodiment, and omits or simplifies points in common with the embodiment.

### 3-1. Variation 1

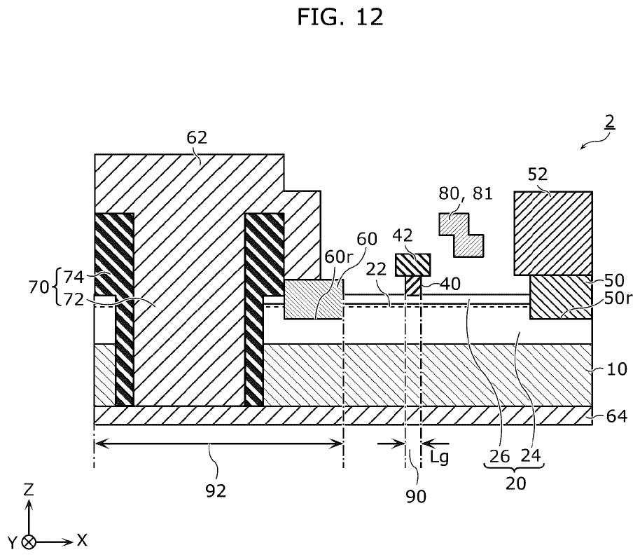

FIG. 12 is a cross-sectional view of semiconductor device for power amplification 2 according to Variation 1.

As shown in FIG. 12, in semiconductor device for power amplification 2, drain electrode 50 and source electrode 60 each include a recessed structure. Specifically, recessed portions (recesses) 50r and 60r that penetrate through AlGaN layer 26 into GaN layer 24 are provided in semiconductor layer 20. It is possible to form recessed portions 50r and 60r by removing, by etching, GaN layer 24 and AlGaN layer 26 at least to a depth at which two-dimensional electron gas 22 is produced. On a lateral face of each of recessed portions 50r and 60r, a hetero interface between AlGaN layer 26 and GaN layer 24 is located, and an end portion of two-dimensional electron gas 22 is exposed.

Drain electrode 50 is provided in contact with the lateral face of recessed portion 50r. Source electrode 60 is provided in contact with the lateral face of recessed portion 60r. In the example shown in FIG. 12, both drain electrode 50 and source electrode 60 are provided to fill recessed portions 50r and 60r, respectively. Accordingly, since drain electrode 50 and source electrode 60 each are in contact with two-dimensional electron gas 22, it is possible to reduce contact resistance and drain-source resistance.

It should be noted that only one of recessed portions 50r and 60r may be provided. For example, recessed portion 50r is not provided, and, as with the embodiment, drain electrode 50 may be disposed on the surface of semiconductor layer 20. Alternatively, recessed portion 60r is not provided, and source electrode 60 may be disposed on the surface of semiconductor layer 20.

### 3-2. Variation 2

FIG. 13 is a cross-sectional view of semiconductor device for power amplification 3 according to Variation 2. As with FIG. 3, FIG. 13 shows an XZ cross section cutting through plate drive line 82.

As shown in FIG. 13, plate drive line 82 is provided away from isolation region 30. Specifically, plate drive line 82 is provided above gate finger 42.

Accordingly, it becomes easier to keep a long distance between plate drive line 82 and gate finger 42. For this reason, since it is possible to reduce gate-source capacitance Cgs, it is possible to improve gain performance of semiconductor device for power amplification 3.

### 3-3. Variation 3

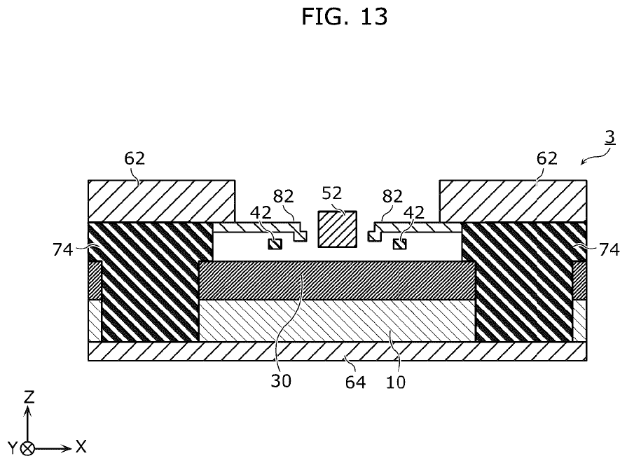

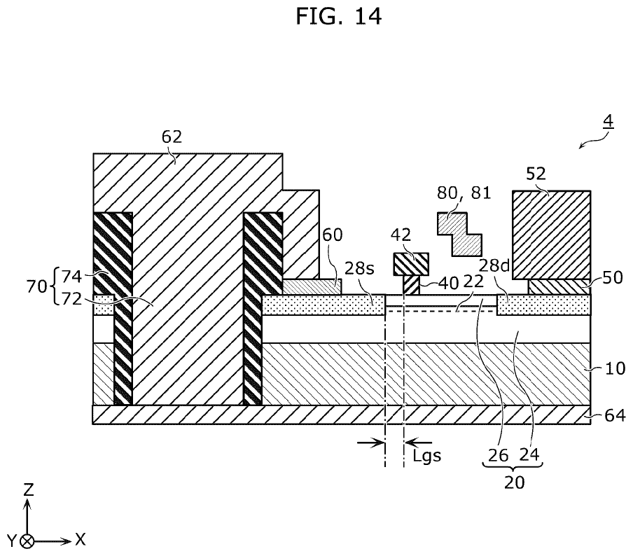

FIG. 14 is a cross-sectional view of semiconductor device for power amplification 4 according to Variation 3.

As shown in FIG. 14, in semiconductor device for power amplification 4, semiconductor layer 20 includes contact layers 28d and 28s. Contact layer 28d is in contact with drain electrode 50 and two-dimensional electron gas 22. Contact layer 28s is in contact with source electrode 60 and two-dimensional electron gas 22. Contact layers 28d and 28s have a resistance lower than that of both GaN layer 24 and AlGaN layer 26.

Contact layers 28d and 28s are formed by reducing the resistance of a portion of semiconductor layer 20 by ion implantation. Specifically, contact layers 28d and 28s are formed by implanting ions of Si etc. into a region that includes at least the hetero interface between GaN layer 24 and AlGaN layer 26 that have been epitaxially grown, that is, a region in which two-dimensional electron gas 22 is produced. Contact layers 28d and 28s are formed by annealing after the ion implantation.

Alternatively, contact layers 28d and 28s may be formed by crystal regrowth after GaN layer 24 and AlGaN layer 26 that have been epitaxially grown are removed by being etched at least to a depth at which two-dimensional electron gas 22 is produced. For example, contact layers 28d and 28s may be epitaxially grown low-resistance semiconductor layers in portions removed from GaN layer 24 and AlGaN layer 26.

After contact layers 28d and 28s are formed, drain electrode 50 and source electrode 60 are formed. Specifically, drain electrode 50 is provided in contact with the top face of contact layer 28d. Source electrode 60 is provided in contact with the top face of contact layer 28s.

As stated above, in semiconductor device for power amplification 4 according to the present variation, semiconductor layer 20 includes contact layer 28s that electrically connects two-dimensional electron gas 22 and source electrode 60 in the surface of semiconductor layer 20.

Accordingly, since the presence of contact layer 28s leads to a decrease in substantial gate-source distance Lgs, it is possible to reduce source resistance. It should be noted that only for the purpose of decreasing gate-source distance Lgs, it is conceivable to dispose source electrode 60 itself close to gate electrode 40. In this case, however, since gate-source capacitance Cgs is increased, a high-frequency property is degraded. The present variation makes it possible to reduce the source resistance while reducing an increase in gate-source capacitance Cgs due to the presence of contact layer 28s.

Moreover, in the present variation, since contact layer 28d is provided, the same applies to drain electrode 50. With regard to drain electrode 50, since field plate 80 supplied with a source electric potential is provided, it is possible to reduce drain resistance while reducing an increase in source-drain capacitance Cds.

It should be noted that only one of contact layers 28s and 28d may be provided. For example, contact layer 28s is provided, and contact layer 28d need not be provided.

### 3-4. Variation 4

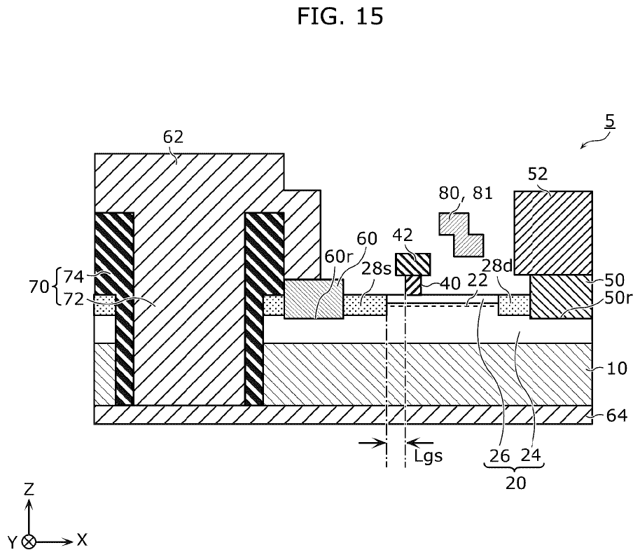

FIG. 15 is a cross-sectional view of semiconductor device for power amplification 5 according to Variation 4.

As shown in FIG. 15, semiconductor device for power amplification 5 includes a configuration obtained by combining drain electrode 50 and source electrode 60 of semiconductor device for power amplification 2 according to Variation 1 and contact layers 28d and 28s of semiconductor device for power amplification 4 according to Variation 3. In other words, semiconductor device for power amplification 5 includes recessed drain electrode 50, recessed source electrode 60, and contact layers 28d and 28s.

As with Variation 3, the present variation makes it possible to reduce source resistance while reducing an increase in gate-source capacitance Cgs. Additionally, it is possible to reduce drain resistance while reducing an increase in source-drain capacitance Cds.

### 3-5. Variation 5

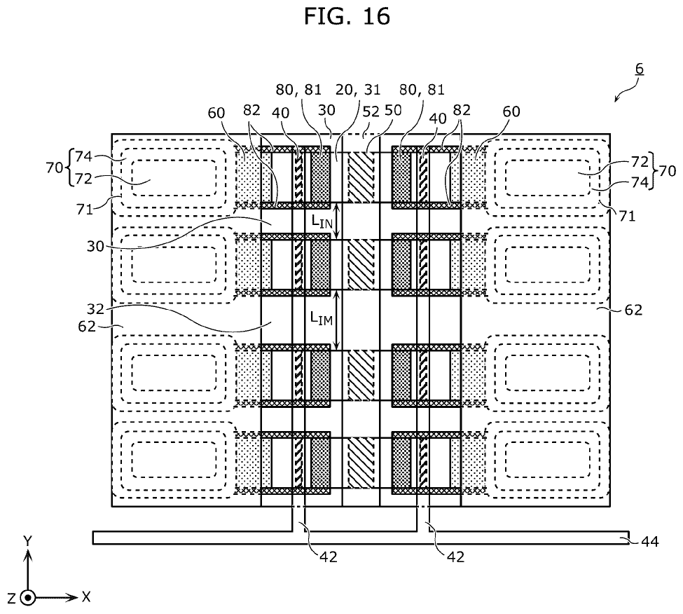

FIG. 16 is a plan view of semiconductor device for power amplification 6 according to Variation 5.

As shown in FIG. 16, in semiconductor device for power amplification 6, isolation regions 30 are not uniform in length in the Y-axis direction. Specifically, semiconductor device for power amplification 6 includes isolation region 32 that differs from isolation region 30 in length in the Y-axis direction. Length L_{IM} of isolation region 32 in the Y-axis direction is greater than length L_{IN} of isolation region 30 in the Y-axis direction.

In the plan view, for example, isolation region 32 is located at the center of semiconductor device for power amplification 6 in the Y-axis direction. In semiconductor device for power amplification 6, heat concentrates more easily at the center than in the outer periphery. By increasing isolation region 32 in a portion at which heat concentrates easily, it is possible to mitigate heat concentration and improve heat dissipation performance.

### 4. Variations of Source Via

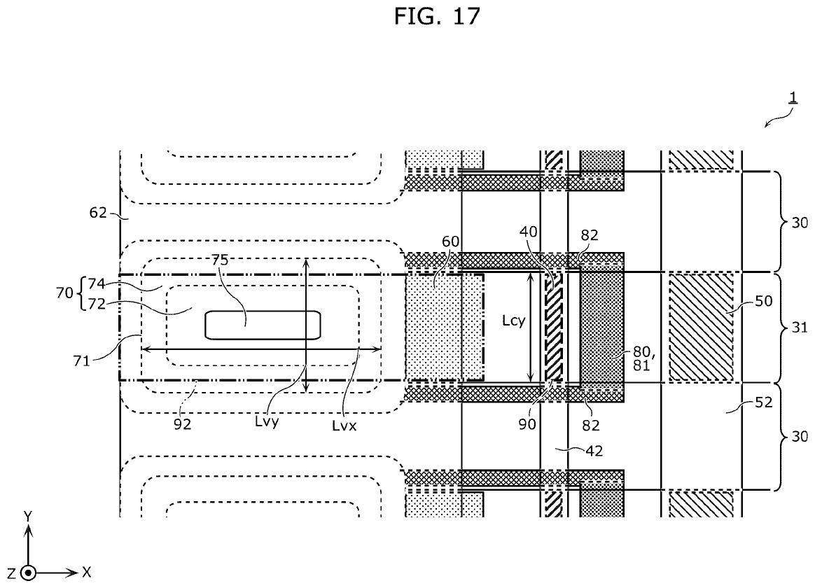

Subsequently, a plurality of variations of source via 70 are described with reference to FIG. 17 to FIG. 25.

FIG. 17 to FIG. 25 each are a plan view of another example of the source via in each of the semiconductor devices for power amplification according to the embodiment and Variations 1 to 5.

### [4-1. Low-Filled Source Via]

First, a low-filled source via is described with reference to FIG. 17.

A low-filled source via is a source via that does not completely fill via hole 71 that penetrates through substrate 10 and semiconductor layer 20, that is, has a filling rate of less than 100%. The filling rate is a ratio of the volume of a metal material disposed in via hole 71 to the capacity of via hole 71.

As shown in FIG. 17, in source via 70, metal filler 72 does not completely fill an area surrounded by metal coating 74. Specifically, as with metal coating 74, in the plan view, metal filler 72 is provided in a ring shape along the lateral faces of via hole 71. In other words, source via 70 includes space 75.

Space 75 penetrates, for example, from the top face of semiconductor layer 20 into the bottom face of substrate 10. An opening of space 75 in the bottom face of substrate 10 is covered with lower electrode 64. It should be noted that portions of the metal material included in metal filter 72 or metal coating 74 may be discretely located in space 75. Although the details are described later, a method for manufacturing a semiconductor device for power amplification includes polishing the bottom face of substrate 10. A portion of metal filler 72 or metal coating 74 that is scraped at the time of polishing may remain in space 75. Metal filler 72 may include a porous structure.

Moreover, although FIG. 17 shows an example in which space 75 is seen in the plan view, that is, an example in which space 75 is open in the top face of semiconductor layer 20, the present disclosure is not limited to this example. Space 75 is not open in the top face of semiconductor layer 20, and may be filled by metal filler 72. In other words, the entire perimeter of space 75 may be covered by any of metal filler 72, metal coating 74, and lower electrode 64.

In the present variation, source via 70 has a filling rate of at least 50%. To put it another way, a conductor inside source via 70 accounts for at least a half of the opening volume of source via 70.

Accordingly, it is possible to improve heat dissipation performance using a metal component having a high heat conductivity. For example, an Si substrate has a thermal resistance higher than that of an SiC substrate. However, since it is possible to improve the heat dissipation performance using source via 70 including a filled metal component, even when the Si substrate is used as substrate 10, it is possible to sufficiently exhibit the properties of semiconductor device for power amplification 1.

### [4-2. Connected Source Via]

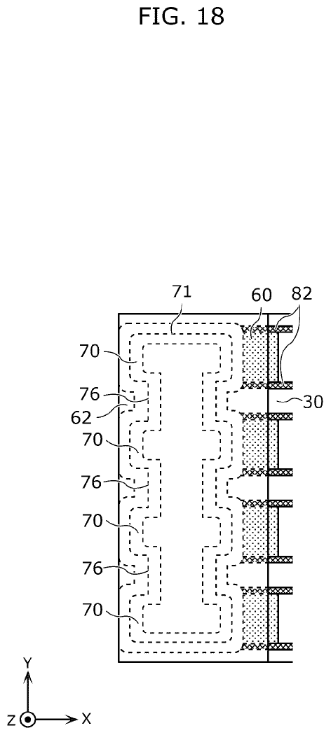

Next, a connected source via is described with reference to FIG. 18.

The connected source via has a configuration in which at least two adjacent source vias are connected. Specifically, as shown in FIG. 18, via connector 76 that connects two source vias 70 is provided. Although FIG. 18 shows an example in which four source vias 70 are connected, the number of source vias 70 connected is not particularly limited. For example, all source vias 70 arranged in the Y-axis direction may be connected, or every N (N is a natural number greater than or equal to 2) source vias 70 may be connected.

A method for forming source vias 70 connected and via connector 76 is similar to a method for forming a plurality of source vias spaced apart from each other, except for a different shape of via hole 71 that penetrates through semiconductor layer 20 and substrate 10. For example, after via hole 71 that extends over a plurality of unit source regions 92 and is in an elongated shape in the Y-axis direction is formed, the lateral faces of via hole 71 are covered with metal coating 74. Subsequently, by filling an area surrounded by metal coating 74 with a metal material, it is possible to form source vias 70 connected and via connector 76.

As stated above, source vias 70 included in adjacent respective unit source regions 92 (not shown in FIG. 18) are connected. In other words, in the plan view, an opening outline of source vias 70, that is, an opening outline of via hole 71 is continuous.

Accordingly, since it is possible to increase a volume occupied by a metal having a high heat conductivity by source vias 70 being connected, it is possible to further improve the heat dissipation performance.

### [4-3. Group Source Via]

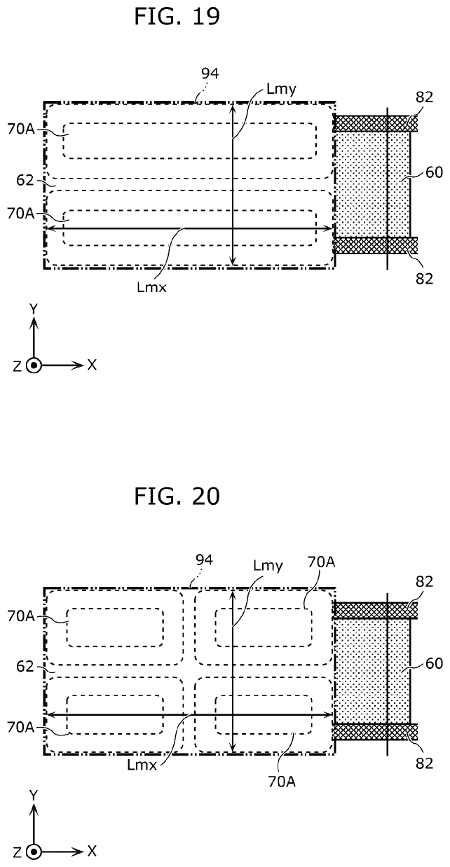

Next, a group source via is described with reference to FIG. 19 to FIG. 25. It should be noted that FIG. 19 to FIG. 29 do not show via hole 71 in consideration of the visibility of the figures. In each figure, the planar shape of an opening outline of via hole 71 is equivalent to the shape of a source via in the figure (specifically, equivalent to and one size smaller than the planar shape of metal coating 74).

The group source via has a configuration in which a plurality of source vias are provided in one unit source region 92. The plurality of source vias are arranged in a two-dimensional array.

In the examples shown in FIG. 19 to FIG. 21, a plurality of source vias 70A whose planar shape is a rectangular shape elongated in the X-axis direction are provided in one unit source region 92 (not shown in each figure). It should be noted that some of the plurality of source vias 70A may be located outside unit source region 92.

In the example shown in FIG. 19, two source vias 70A are arranged in the Y-axis direction. In the example shown in FIG. 20, four source vias 70A are arranged in a two-by-two matrix.

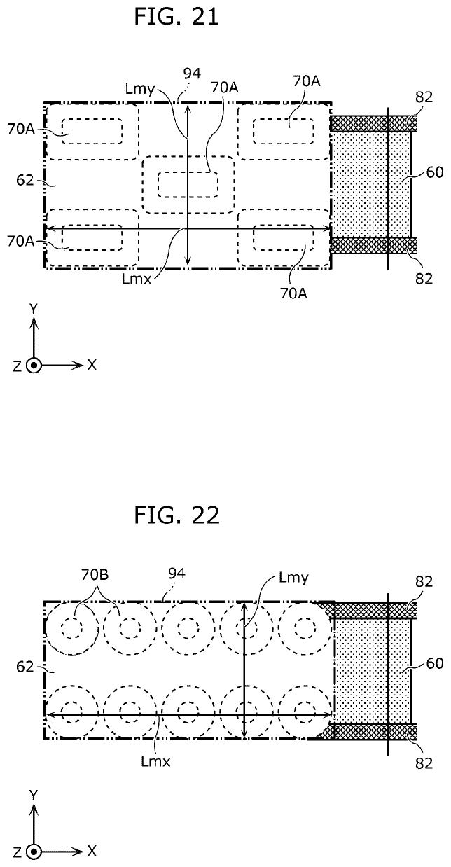

In the example shown in FIG. 21, five source vias 70A are arranged in a checker pattern. Specifically, four source vias 70A are arranged in the diagonal directions of one source via 70A, centering on one source via 70a. No source vias 70A are disposed to the top, bottom, right, and left (the positive and negative sides of the X-axis direction and the positive and negative sides of the Y-axis direction) of central source via 70A.

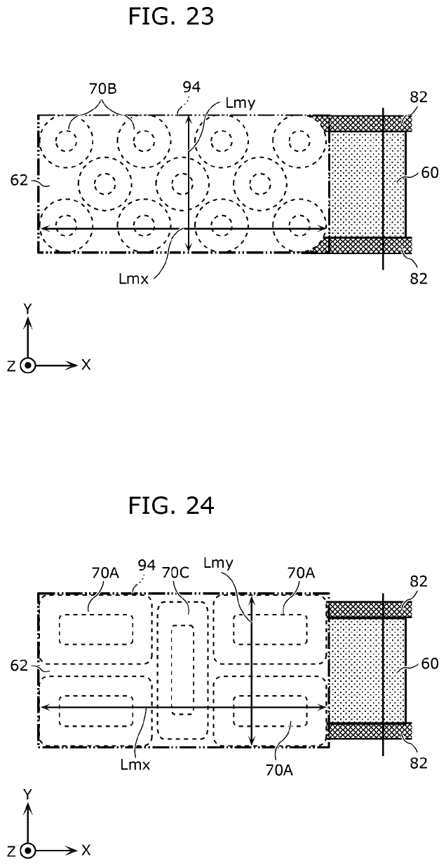

The planar shape of a source via provided in one unit source region 92 need not be the rectangular shape elongated in the X-axis direction. In the examples shown in FIG. 22 and FIG. 23, a plurality of source vias 70B whose planar shape is a circular shape are provided in one unit source region 92. Since source via 70B whose planar shape is the circular shape has no anisotropy in shape, it is easy to perform metal filling on source via 70B. Since it is possible to improve the accuracy of metal filling, it is possible to contribute to the improvement of heat dissipation performance.

In the example shown in FIG. 22, ten source vias 70B are arranged in a two-by-five matrix. In the example shown in FIG. 23, eleven source vias 70B are arranged to cause, for each row, the center positions of source vias 70B to be displaced in the X-axis direction. Specifically, source vias 70B are arranged to form an isosceles triangle when the centers of every three adjacent source vias 70B are connected.

It should be noted that the arrangements shown in FIG. 21 and FIG. 23 are examples of a staggered arrangement. The staggered arrangement refers to an arrangement in which two adjacent source vias are displaced in at least one of the X-axis direction or the Y-axis direction. The amount of displacement may be a small amount of displacement to the extent that portions of the source vias face each other, or a large amount of displacement to the extent that no portions of the source vias face each other completely (overlap each other when viewed from one direction). Source vias may be arranged so that the source vias do not overlap, and sets each of which includes a plurality of source vias arranged in a matrix may be arranged in a staggered pattern.

Although the shape and size of the plurality of source vias included in one unit source region 92 are identical in the examples shown in FIG. 19 to FIG. 23, the present disclosure is not limited to the examples. A plurality of source vias included in one unit source region 92 may include source vias that differ in shape and size.

In the example shown in FIG. 24, four source vias 70A whose planar shape is a rectangular shape elongated in the X-axis direction are arranged next to one source via 70C whose planar shape is a rectangular shape elongated in the Y-axis direction. Four source vias 70A are arranged in a two-by-two matrix, and source via 70C is disposed between the rows.

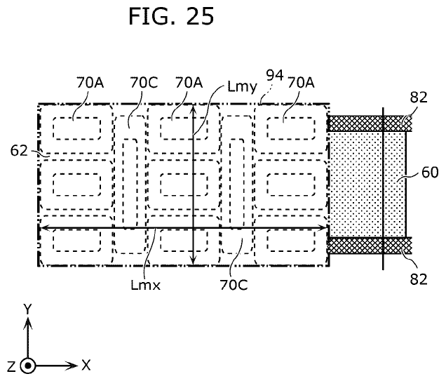

In the example shown in FIG. 25, nine source vias 70A are arranged next to two source vias 70C. Nine source vias 70A are arranged in a three-by-three matrix, and each source via 70C is disposed between the corresponding rows.

As stated above, for example, the number of at least one source via 70A, 70B, or 70C included in unit source region 92 may be at least two. In this case, minimum rectangular region 94 is a region that surrounds all source vias 70A, 70B, or 70C provided in unit source region 92 in the plan view.

Accordingly, since the shape of each of source vias 70A, 70B, and 70C is reduced, it is easy to perform metal filling. Since the metal filling rate of each of source vias 70A, 70B, and 70C is increased, it is possible to further improve the heat dissipation performance.

In each of the examples shown in FIG. 19 to FIG. 25, minimum rectangular region 94 is indicated by the thick dash-double-dot line. Minimum rectangular region 94 is a rectangular region that surrounds at least some of all source vias 70A, 70B, and/or 70C included in one unit source region 92, and is a region that includes parallel sides in each of the X-axis direction and the Y-axis direction and has the smallest area.

The length of minimum rectangular region 94 in the X-axis direction is denoted by Lmx, and the length of minimum rectangular region 94 in the Y-axis direction is denoted by Lmy. Here, Lmx>Lmy is satisfied. Accordingly, as with the single source via (specifically source via 70), it is possible to improve the heat dissipation performance in the X-axis direction.

Moreover, for example, at least one source via 70A, 70B, or 70C is arranged in a two-dimensional matrix in the plan view.

For this reason, it is possible to prevent heat from concentrating locally, and improve the heat dissipation performance.

It should be noted that FIG. 19 to FIG. 25 each merely show the example of the shape of each of the plurality of source vias and the arrangement of the plurality of source vias, and the present disclosure is not limited to the above examples. A source via whose planar shape is a rectangle need not have longer sides parallel to the X-axis or the Y-axis, and may have longer sides that extend in a direction obliquely crossing the X-axis or the Y-axis. Moreover, the shape of each of a plurality of source vias may be a polygon other than a rectangle such as a square and a hexagon, or may be, for example, an ellipse. Furthermore, the plurality of source vias need not be arranged regularly, and may be arranged randomly. Additionally, for example, in the plan view, the total area of source vias that occupy unit source region 92 may account for more than half the area of unit source region 92, or may account for less than half the area of unit source region 92. The number, shape, arrangement, etc. of source vias may be changed appropriately, based on a condition such as processability.

### 5. Variations of Plate Drive Line

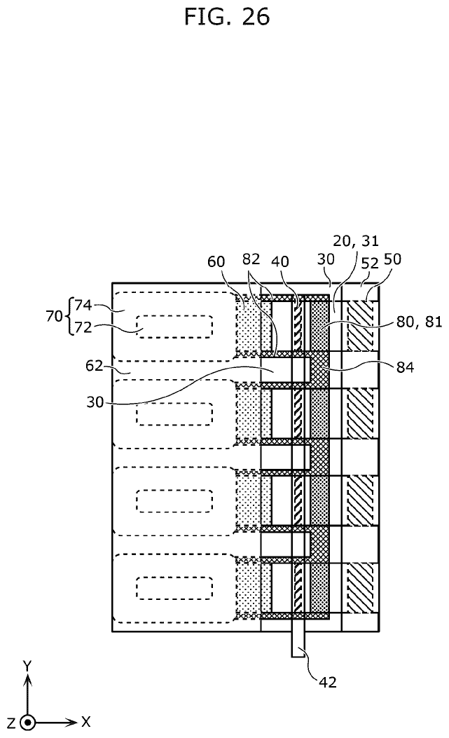

Subsequently, a plurality of variations of plate drive line 82 are described with reference to FIG. 26 to FIG. 29.

FIG. 26 to FIG. 29 each are a plan view of another example of the plate drive line in each of the semiconductor devices for power amplification according to the embodiment and Variations 1 to 5.

In the example shown in FIG. 26, connecting line 84 that connects two adjacent unit plates 81 among a plurality of unit plates 81 of field plate 80 is provided. Connecting line 84 is disposed between gate finger 42 and drain finger 52. Connecting line 84 is provided next to unit plate 81 of field plate 80 in the Y-axis direction. The length of connecting line 84 in the X-axis direction is equal to the length of unit plate 81 in the X-axis direction.

Connecting line 84 is formed using a conductive material. For example, it is possible to form connecting line 84 integrally using the same material as the material of plate drive line 82. Alternatively, connecting line 84 may be integrally formed using the same material as the material of field plate 80. In other words, it is possible to regard connecting line 84 as a portion of plate drive line 82 or a portion of field plate 80.

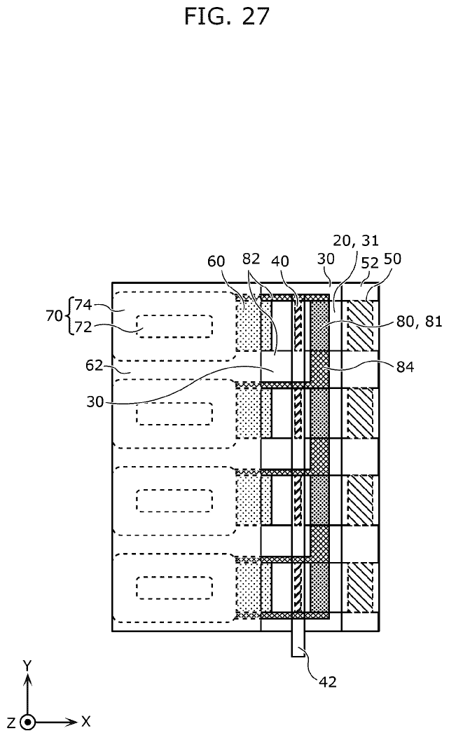

The example shown in FIG. 27 is obtained by decreasing the number of plate drive lines 82 for each unit plate 81 in the example shown in FIG. 26 by 1. To put it another way, unit plate 81 and plate drive line 82 correspond to each other on a one-to-one basis. A decrease in the number of plate drive lines 82 makes it possible to reduce gate-source capacitance Cgs. By reducing gate-source capacitance Cgs, it is possible to improve gain performance of the semiconductor device for power amplification.

As stated above, the semiconductor device for power amplification according to the embodiment or each of the variations may include connecting line 84 that connects two adjacent unit plates 81. Connecting line 84 may be located between gate finger 42 and drain finger 52 in the plan view.

By connecting the plurality of unit plates 81 in the Y-axis direction, it is possible to reduce wiring resistance of field plate 80. Accordingly, it becomes easier to ensure in-plane uniformity of a source electric potential of field plate 80.

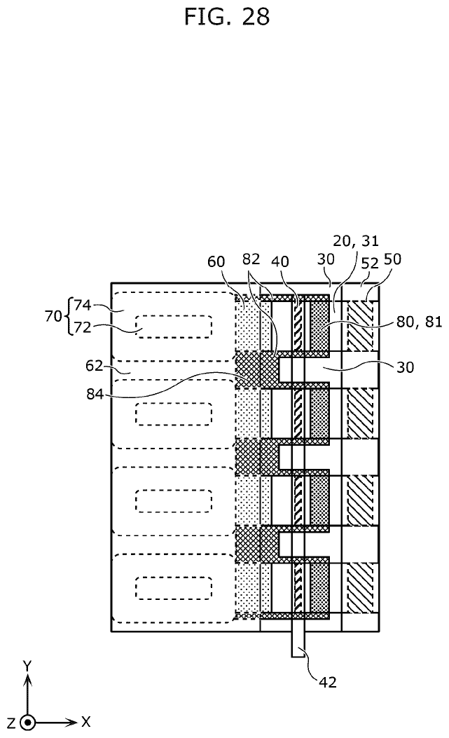

The example shown in FIG. 28 differs from the example shown in FIG. 26 in the location of connecting line 84. Specifically, connecting line 84 is provided on the opposite side of drain finger 52 with respect to gate finger 42. More specifically, connecting line 84 is provided in contact with source connector 62.

Accordingly, since this further increases an area that contributes to heat dissipation, it is possible to further enhance a heat dissipation effect.

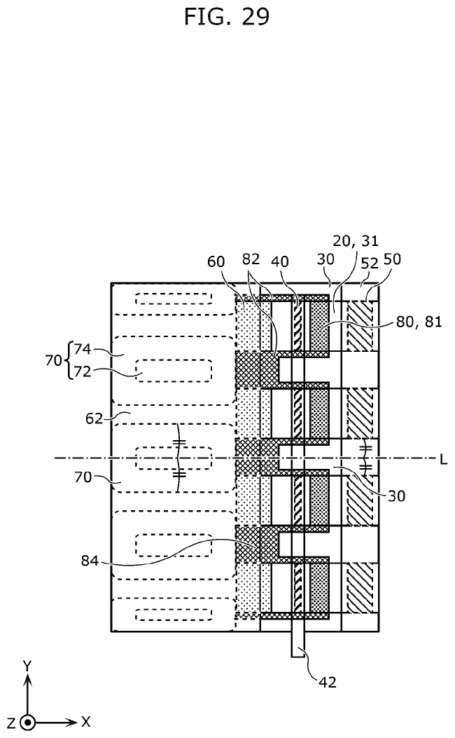

It should be noted that the location of source via 70 may be changed in the example shown in FIG. 28. Specifically, as shown in FIG. 29, the center position of source via 70 coincides with the center position of isolation region 30 between adjacent unit channel regions 90 in the Y-axis direction. More specifically, the center of source via 70 in the Y-axis direction and the center of isolation region 30 in the Y-axis direction are located on straight line L that extends in the X-axis direction. In this case, connecting line 84 is in contact with source via 70.

Accordingly, since this makes it easier for heat diffused via connecting line 84 to be conducted to source via 70, it is possible to further enhance the heat dissipation effect.

It should be noted that, in the examples shown in FIG. 26 to FIG. 29, source via 70 may be the low-filled source via shown in FIG. 17, the connected source via shown in FIG. 18, or the group source via shown in each of FIG. 19 to FIG. 25.

### 6. Manufacturing Method

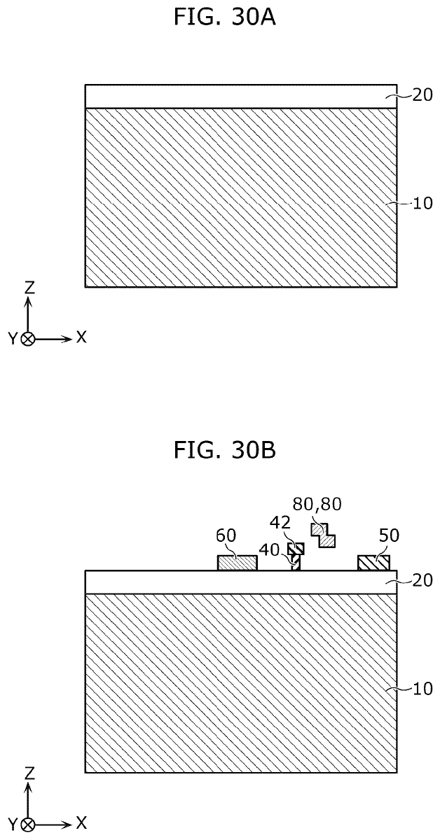

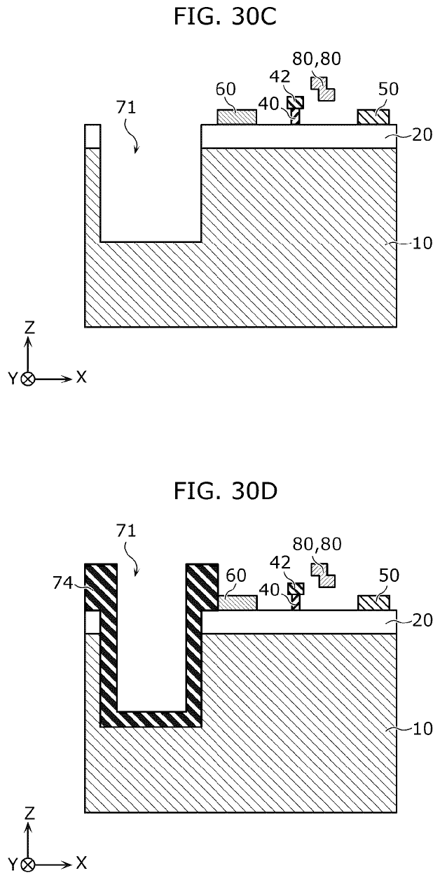

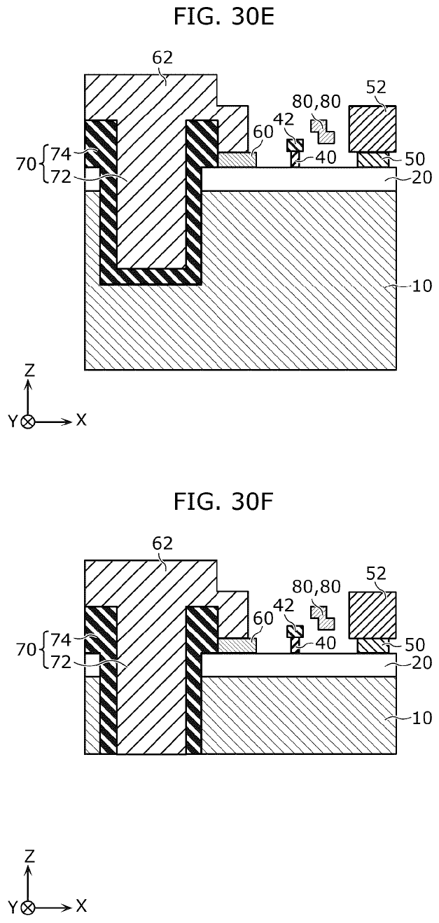

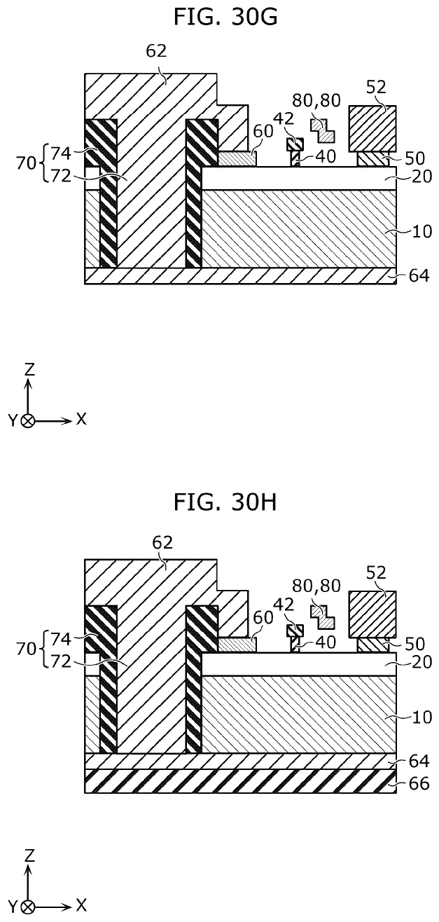

Subsequently, a method for manufacturing each of the semiconductor devices for power amplification according to the embodiment and the variations described above is described with reference to FIG. 30A to FIG. 30H. FIG. 30A to FIG. 30H each are a cross-sectional view for illustrating a process in the method for manufacturing each of the semiconductor devices for power amplification according to the embodiment and the variations. Each of the cross-sectional views shows a cross section corresponding to line II-II shown in FIG. 1, that is, a cross section that cuts through source electrode 60, gate electrode 40, and drain electrode 50. Thicknesses, materials, etc. in the following description are mere examples, and the present disclosure is not limited to the examples shown below.

First, as shown in FIG. 30A, semiconductor layer 20 is formed on a principal surface of substrate 10. Semiconductor layer 20 is formed by forming a GaN semiconductor film while adjusting film formation conditions using an epitaxial growth method. It should be noted that substrate 10 used for forming semiconductor layer 20 is a substrate that is thicker than substrate 10 after manufacturing, and has a thickness of, for example, 1000 μm. Semiconductor layer 20 has a thickness of, for example, 2 μm.

Moreover, although not shown in the figure, isolation region 30 is formed by performing ion implantation on a prescribed region of semiconductor layer 20 after growth. Furthermore, contact layers 28d and 28s shown in FIG. 14 etc. may be formed by performing the ion implantation on the prescribed region of semiconductor layer 20 after growth.

Next, as shown in FIG. 30B, gate electrode 40, drain electrode 50, source electrode 60, gate finger 42, and field plate 80 are formed. For example, after a metal film is formed by vapor deposition or sputtering, gate electrode 40, drain electrode 50, source electrode 60, gate finger 42, and field plate 80 are formed by patterning the metal film into a prescribed shape by etching. A liftoff method may be used for forming the electrodes etc. It should be noted that when the same metal material can be used as with drain electrode 50 and source electrode 60, it is possible to form electrodes in the same process. Moreover, before each of gate finger 42 and field plate 80 is formed, an insulating film not shown in the figure is formed by, for example, plasma chemical vapor deposition (CVD). The electrodes etc. each have a thickness of, for example, 0.2 μm. After the electrodes etc. are formed, an insulating film for protecting the electrodes etc. may be formed by plasma CVD.

Then, as shown in FIG. 30C, via hole 71 is formed. Via hole 71 is formed by, for example, etching. Via hole 71 is formed to penetrate through semiconductor layer 20 and carve out at least a portion of substrate 10. Via hole 71 has a depth of, for example, 150 μm. The planar shape of via hole 71 is, for example, a rectangle whose shorter side has a length of at most 20 μm. It should be noted that the shapes and number of via holes 71 are adjusted according to the shapes and number of source vias 70. Not only the example shown in FIG. 1 but also the examples etc. shown in FIG. 18 to FIG. 25 are applicable.

After that, as shown in FIG. 30D, metal coating 74 is formed along the lateral faces of via hole 71. Metal coating 74 is formed by, for example, plating. As an example, an Au film that has a thickness of 5 μm is formed. Metal coating 74 is formed to have a substantially even thickness along the lateral faces and bottom face of via hole 71. In addition, metal coating 74 is also provided in an edge portion of the opening of via hole 71 on a semiconductor layer 20 side. Although metal coating 74 is in contact with source electrode 60 in the example shown in FIG. 30D, metal coating 74 need not be in contact with source electrode 60.

Next, as shown in FIG. 30E, metal filler 72 is formed. Metal filler 72 is formed by, for example, plating. As an example, an Au film or a Cu film that has a thickness of 5 μm is formed. Accordingly, it is possible to fill via hole 71 whose shorter side has a length of 20 μm. Filling of via hole 71 is made possible by adjusting the thicknesses of metal coating 74 and metal filler 72 according to the size of via hole 71. It should be noted that, as shown in FIG. 17, since via hole 71 need not be filled completely, metal coating 74 and metal filler 72 may be formed to have a certain thickness regardless of the size of via hole 71. Accordingly, source via 70 is formed.

Moreover, in the example shown in FIG. 30E, drain finger 52 and source connector 62 are formed in the same process as the formation of metal filler 72. Source connector 62 is formed integrally with metal filler 72. A recessed portion that is recessed downward from the top face of source connector 62 may be formed in a portion of the top face of source connector 62 that overlaps via hole 71 in the plan view. In other words, the top face of source connector 62 need not be flat in the portion overlapping via hole 71 in the plan view.

Then, as shown in FIG. 30F, the bottom face (back face) of substrate 10 is polished. The polishing is performed until at least source via 70 is exposed. For example, the polishing is performed until a thickness from the top face of semiconductor layer 20 to the bottom face of substrate 10 becomes approximately 100 μm. Accordingly, it is possible to make the semiconductor device for power amplification thinner.

After that, as shown in FIG. 30G, lower electrode 64 is formed. For example, a metal film that comprises a metal or an alloy that includes at least one of Ti, Ni, Cr, W, Au, or Ag is formed as lower electrode 64 by vapor deposition or plating etc., to cover the entirety of the bottom face of substrate 10. Since source via 70 is exposed to the bottom face of substrate 10 by the polishing, lower electrode 64 and source via 70 are made contact with each other and electrically conductive. Lower electrode 64 has a thickness of, for example, approximately 1 μm. As an example, a metal stack that is obtained by stacking, from the substrate 10 side, a Ti film having a thickness of 100 nm, an Ni film having a thickness of 600 nm, and an Au film having a thickness of 200 nm in stated order is formed as lower electrode 64.

Each of the semiconductor devices for power amplification according to the embodiment and the variations described above is manufactured through the above processes.

It should be noted that, as shown in FIG. 30H, the semiconductor device for power amplification manufactured may be packaged as necessary. Specifically, the semiconductor device for power amplification is fixed to a package material that is formed of, for example, a resin, a metal, or a ceramic, using die bond material 66 such as AuSn or Ag.

### OTHER EMBODIMENTS

Although one or more semiconductor devices for power amplification according to one or more aspects have been described based on the embodiment, the variations, etc. above, the present disclosure is not limited to the embodiment etc. Forms obtained by various modifications to the present embodiment that can be conceived by a person skilled in the art as well as forms created by combining constituent elements in different embodiments are included in the scope of the present disclosure, as long as they do not depart from the essence of the present disclosure.

For instance, although the example in which the plurality of gate electrodes 40, the plurality of drain electrodes 50, and the plurality of source electrodes 60 are arranged in the Y-axis direction is shown, the present disclosure is not limited to this example. In other words, the plurality of gate electrodes 40, the plurality of drain electrodes 50, and the plurality of source electrodes 60 need not be separated in the Y-axis direction. For example, the plurality of gate electrodes 40 arranged in the Y-axis direction may be one gate electrode obtained by connecting the plurality of gate electrodes 40. To put it another way, the one gate electrode may be provided not only on semiconductor layer 20 but also on isolation region 30. The same applies to the plurality of drain electrodes 50 and the plurality of source electrodes 60.

Moreover, although the example in which one source via 70 or the plurality of source vias 70A, 70B, or 70C are provided in each of the plurality of unit source regions 92 is shown, the present disclosure is not limited to this example. Unit source region 92 in which no source via 70, 70A, 70B, or 70C is provided may be present.

Alternatively, a source via need not be provided in any of the plurality of unit source regions 92. For example, as with semiconductor device for power amplification 1x according to the comparative example, source via 70x may be provided outside a source region.

Furthermore, although the example in which all of source vias 70, 70A, 70B, and 70C each include metal filler 72 and metal coating 74 is shown, the present disclosure is not limited to this example. Each of source vias 70, 70A, 70B, and 70C may include only metal filler 72 or may include only metal coating 72.

Moreover, when the plurality of unit plates 81 are connected to each other, the plurality of plate drive lines 82 need not be provided. In other words, a source electric potential may be supplied to each of the plurality of unit plates 81 in the Y-axis direction.

Furthermore, various changes, substitutions, additions, omissions, etc. can be carried out in each of the above embodiments within the scope of the claims or its equivalents.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure can be used as a semiconductor device for power amplification that is capable of reducing property degradation due to heat, and can be used as a high-frequency transistor or can be used for various electronic devices such as a communication device.

1. A semiconductor device for power amplification comprising:
a substrate;
a lower electrode provided below the substrate;
a semiconductor layer that is provided above the substrate and includes a plurality of active layers comprising group-III nitride, and in which two-dimensional electron gas is produced in a hetero interface of the plurality of active layers;
a source electrode and a drain electrode that are provided above the semiconductor layer, spaced apart from each other, and electrically connected to the two-dimensional electron gas;
a gate electrode that is spaced apart from the source electrode and the drain electrode and is in contact with the semiconductor layer;
a gate finger that is in contact with and covers all of a plurality of gate electrodes arranged linearly in a first direction, the plurality of gate electrodes each being the gate electrode; and
a drain finger that is in contact with and covers all of a plurality of drain electrodes arranged linearly in the first direction, the plurality of drain electrodes each being the drain electrode,
wherein a plurality of gate fingers are arranged in a second direction orthogonal to the first direction and supplied with a same electric potential, the plurality of gate fingers each being the gate finger,
in a plan view of the substrate, the semiconductor layer is divided into an active region containing the two-dimensional electron gas and an isolation region not containing the two-dimensional electron gas,
in the plan view, a channel region includes a plurality of unit channel regions that are separated by the isolation region and arranged in the first direction, the channel region being an overlapping portion of the active region and the plurality of gate electrodes,
the source electrode includes a plurality of unit source electrodes each of which faces a corresponding one of the plurality of unit channel regions,
a plurality of unit source regions each include at least one source via that contains a conductor that penetrates through the substrate and the semiconductor layer and is in contact with the lower electrode that is supplied with a same electric potential as an electric potential supplied to the source electrode, the plurality of unit source regions each including a corresponding one of the plurality of unit source electrodes, and
in the plan view, a length of a side of a minimum rectangular region in the second direction is greater than a length of a side of the minimum rectangular region in the first direction, the minimum rectangular region surrounding the at least one source via.

2. The semiconductor device for power amplification according to claim 1,
wherein a total number of the at least one source via is one, and
in the plan view, a length of an opening outline of the one source via in the second direction is greater than a length of the opening outline in the first direction.

3. The semiconductor device for power amplification according to claim 2,
wherein the length of the opening outline in the first direction is greater than a length of a unit channel region in the first direction, the unit channel region being included in the plurality of unit channel regions.

4. The semiconductor device for power amplification according to claim 2,
wherein source vias each included in a corresponding one of adjacent unit source regions are connected to each other, the source vias each being the at least one source via, the adjacent unit source regions being included in the plurality of unit source regions.

5. The semiconductor device for power amplification according to claim 1,
wherein a total number of the at least one source via is at least two.

6. The semiconductor device for power amplification according to claim 5,
wherein the at least one source via is arranged two-dimensionally in the plan view.

7. The semiconductor device for power amplification according to claim 1,
wherein the at least one source via is provided in each of the plurality of unit source regions.

8. The semiconductor device for power amplification according to claim 1,
wherein the conductor contained in the at least one source via occupies at least half of an opening volume of the at least one source via.
